(19) United States
(12) Patent Application Publication
(10) Pub. No.: US 2017/0317471 A1
(43) Pub. Date: Nov. 2, 2017

(54) AN OPTICAL DEVICE AND A METHOD FOR FABRICATING THEREOF

(71) Applicant: Agency for Science, Technology and Research, Singapore (SG)

(72) Inventors: Ter-hoe Lor, Singapore (SG); Qian Wang, Singapore (SG); Vivek Krishnamurthy, Singapore (SG)

(73) Assignee: Agency for Science, Technology and Research, Singapore (SG)

(21) Appl. No.: 15/522,210

(22) PCT Filed: Nov. 6, 2015
(86) PCT No.: PCT/SG2015/050438

§ 371 Date: Apr. 26, 2017

(30) Foreign Application Priority Data
Nov. 10, 2014 (SG) 10201407392X

(51) Int. Cl. H01S 5/12; H01S 5/22; H01S 5/125; H01S 5/10; H01S 5/343; H01S 5/02

(52) U.S. Cl. CPC H01S 5/1237; H01S 5/34306; H01S 5/22; H01S 5/021; H01S 5/1032; H01S 5/1014; H01S 5/125

(57) ABSTRACT

According to various embodiments, there is provided an optical device including a first waveguide configured to guide a light wave along a longitudinal axis; a first grating at least partially formed in the first waveguide, the first grating arranged away from the longitudinal axis in a first direction; and a second grating at least partially formed in the first waveguide, the second grating arranged away from the longitudinal axis in a second direction; wherein the second direction is different from the first direction.

### CROSS-REFERENCE TO RELATED APPLICATIONS

This application claims the benefit of Singapore Patent Application number 10201407392X filed 10 Nov. 2014, the entire contents of which are incorporated herein by reference for all purposes.

### TECHNICAL FIELD

The present invention relates to optical devices, methods for fabricating optical devices and methods for providing laser beams.

### BACKGROUND

In recent years, the rise in the use of online multimedia, social media and the Internet of Things initiative have fueled the planet-wide exponential growth in data. Large amounts of data need to be stored, transmitted and processed. Traditional metallic copper that interconnects the data processing system is limited in bandwidth and energy inefficient. Hence, optical data interconnect platforms have begun to transition or extend from long distance or long-haul communications to ultra-short reach (<100 m) and even to inter-chip and possibly intra-chip distances in the order of centimeters or less. Recently, Cloud Computing, Cloud Storage and exascale high performance computing at data centers with data storage and data communication infrastructures employing optical interconnect (OI) in ultra-short-reach regime have begun to play a key role to address the need of the Big Data era. The key to the wide-spread deployment of such OI infrastructure and platform is to lower the cost for manufacturing such optical data interconnect platforms. The cost for OI platforms and components can be reduced by optoelectronic multifunctional integration on silicon. A key component of such OI platforms is the high speed active optical cable (AOC) that connects the backplane of servers and computers at data centers. The key function for the AOC is to provide high capacity optical data transmission in terms of speed, energy efficiency and reliability with low manufacturing cost.

Silicon (Si) photonics has emerged in recent years as a viable platform for OI to address the need of the Big Data communications. The high index contrast of Si and SiO₂ allows ultra-high density integration of Si waveguide on a chip. Si-photonics built on silicon-on-insulator (SOI) substrate allows co-integration of SOI-based Si-photonic waveguide and CMOS electronics, thereby lowering the cost of manufacturing such OI infrastructure by leveraging on the existing low-cost and large scale CMOS manufacturing capability.

AOCs consist of optical fiber-to-chip with integrated optoelectronic transceivers on the chip. The key components in the AOC are the integrated transmitters on Si-photonic chip. Transmitters function to perform electrical to optical conversion of the digital data imparting it into guided laser beam in Si waveguide. For most suppliers of AOC, the integrated optoelectronic transceivers employ SOI-based modulators, which act as high speed optical shutters on guided laser beam in the SOI based Si-waveguide. The laser beam comes from a discrete laser diode flip-chip bonded to the Si-photonic transceiver chip. High capacity transmission AOC requires the implementation of wavelength division multiplexing (WDM) based laser light source. That is, laser beams of various wavelengths with each laser-wavelength being carrier for multi-gigabits/sec data rate. Due to the discrete nature, flip-chip bonded laser light cannot scale up in capacity in terms for WDM implementation.

Therefore, there may be a need for a scalable laser diode.

### SUMMARY

According to various embodiments, there may be provided an optical device including a first waveguide configured to guide a light wave along a longitudinal axis; a first grating at least partially formed in the first waveguide, the first grating arranged away from the longitudinal axis in a first direction; and a second grating at least partially formed in the first waveguide, the second grating arranged away from the longitudinal axis in a second direction; wherein the second direction is different from the first direction.

According to various embodiments, there may be provided a method for providing a laser beam, the method including guiding a light wave along a longitudinal axis of a first waveguide; providing a first grating away from the longitudinal axis in a first direction, the first grating being at least partially formed in the first waveguide; and providing a second grating away from the longitudinal axis in a second direction, the second grating being at least partially formed in the first waveguide; wherein the second direction is different from the first direction.

According to various embodiments, there may be provided a method for fabricating an optical device, the method including providing a first waveguide configured to guide a light wave along a longitudinal axis; forming a first grating at least partially in the first waveguide, wherein the first grating is arranged away from the longitudinal axis in a first direction; and forming a second grating at least partially in the first waveguide, wherein the second grating is arranged away from the longitudinal axis in a second direction; wherein the second direction is different from the first direction.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments are described with reference to the following drawings, in which:

FIG. 1A shows a schematic diagram of a prior art optical device.

FIG. 1B shows a table listing the limitations of a prior art optical device.

FIG. 2A shows a conceptual diagram of an optical device according to various embodiments.

FIG. 2B shows a conceptual diagram of an optical device according to various embodiments.

FIG. 3 shows a flow diagram of a method for providing a laser beam according to various embodiments.

FIG. 4 shows a flow diagram of a method for fabricating an optical device according to various embodiments.

FIG. 5A shows a schematic top view of an optical device according to various embodiments.

FIG. 5B shows a schematic top view of an optical device according to various embodiments.

FIG. 6 shows a schematic cross-sectional view of an optical device according to various embodiments.

FIG. 7A shows a schematic top view of gratings of an optical device according to various embodiments.

FIG. 7B shows a schematic longitudinal cross-sectional view of an optical device according to various embodiments and optical mode profile diagrams of the optical device.

FIG. 8 shows optical mode profile diagrams of an optical device according to various embodiments.

FIG. 9 shows scanning electron microscope diagrams of an optical device according to various embodiments.

FIG. 10 shows a graph showing the relationship of the grating coupling coefficient with the grating gap width for various ridge widths at a grating etch-depth of 240 nm, for an optical device according to various embodiments.

FIG. 11 shows a graph showing the relationship between the grating coupling coefficient with the ridge width for various grating etch depths and various grating gap widths, for an optical device according to various embodiments.

FIG. 12 shows a schematic top-down view of the gratings on an optical device according to various embodiments.

FIG. 13 shows a graph showing a reflection of the λ/4-shifted DFB grating plotted against a wavelength for an optical device according to various embodiments.

FIG. 14 shows a graph showing a designed emission peak of the λ/4-shifted DFB grating of an optical device according to various embodiments.

FIG. 15 shows a longitudinal cross-sectional view of an optical device according to various embodiments.

FIG. 16 shows a graph showing the 2-D Finite-Difference-Time-Domain (FDTD) simulation of light-wave propagation in an up-down coupler of the optical device of FIG. 15.

FIG. 17 shows a graph showing a normalized light intensity plotted against a translational position on a SOI waveguide through an up-down coupler, in an optical device according to various embodiments.

FIG. 18A-18C show top views of up-down couplers according to various embodiments.

FIG. 19 shows a cross-sectional view at the tip of an up-down coupler.

FIG. 20 shows a table listing the epi-layers in a III-V epitaxy of an optical device according to various embodiments.

FIG. 21 shows a schematic diagram of an analytical model used to calculate the threshold gain of a λ/4 shifted DFB laser diode structure according to various embodiments.

FIG. 22 shows a Table listing down the laser diode material and device parameters that may be used for calculating the threshold currents for optical devices according to various embodiments.

FIG. 23A shows a graph showing the threshold current plotted against the cavity length of a λ/4-shifted DFB laser diode.

FIG. 23B shows a graph showing the threshold current plotted against the normalized coupling coefficient for a λ/4-shifted DFB laser diode.

FIG. 24 shows a graph showing the threshold current plotted against the cavity length of a λ/4-shifted DFB laser diode.

FIG. 25 shows a graph showing the differential quantum efficiency of an optical device according to various embodiments, plotted against the cavity length.

FIG. 26A shows a schematic top view diagram of an optical device according to various embodiments.

FIG. 26B shows a schematic top view diagram of an optical device according to various embodiments.

FIG. 27 shows a cross-sectional view of the optical device of FIG. 26A, cut along an axis perpendicular to the longitudinal axis.

FIG. 28 shows a graph showing the DBR reflectance plotted against a number of mirror pairs for an optical device according to various embodiments.

FIG. 29 shows an analytical model used for derivation of characteristic equation for threshold condition.

FIG. 30 shows a graph showing the threshold current plotted against cavity length of a λ/4-shifted DFB LD with zero end facet reflectivities at both ends.

FIG. 31 shows a graph showing the threshold current plotted against cavity length.

FIG. 32 shows a graph showing the differential quantum efficiency plotted against cavity length.

FIG. 33 shows a graph showing threshold current plotted against cavity length.

FIG. 34 shows a graph showing the threshold current plotted against total cavity length.

FIG. 35 shows a top-down schematic diagram of an optical device according to various embodiments.

FIG. 36 shows a schematic diagram of an optical device according to various embodiments.

FIG. 37 shows a schematic diagram of an optical device according to various embodiments.

FIG. 38 shows a schematic diagram showing a transmitter chip according to various embodiments.

FIG. 39 shows a schematic diagram of a transmitter chip according to various embodiments

FIG. 40 shows a schematic diagram of a multi-core chip according to various embodiments.

### DESCRIPTION

Embodiments described below in context of the devices are analogously valid for the respective methods, and vice versa. Furthermore, it will be understood that the embodiments described below may be combined, for example, a part of one embodiment may be combined with a part of another embodiment.

In order that the invention may be readily understood and put into practical effect, particular embodiments will now be described by way of examples and not limitations, and with reference to the figures.

Various embodiments are provided for devices, and various embodiments are provided for methods. It will be understood that basic properties of the devices also hold for the methods and vice versa. Therefore, for sake of brevity, duplicate description of such properties may be omitted.

It will be understood that any property described herein for a specific device may also hold for any device described herein. It will be understood that any property described herein for a specific method may also hold for any method described herein. Furthermore, it will be understood that for any device or method described herein, not necessarily all the components or steps described must be enclosed in the device or method, but only some (but not all) components or steps may be enclosed.

The term “coupled” (or “connected”) herein may be understood as electrically coupled or as mechanically coupled, for example attached or fixed, or just in contact without any fixation, and it will be understood that both direct coupling or indirect coupling (in other words: coupling without direct contact) may be provided.

In recent years, the rise in the use of online multimedia, social media and the Internet of Things initiative have fueled the planet-wide exponential growth in data. Large amounts of data need to be stored, transmitted and processed. Traditional metallic copper that interconnects the data processing system is limited in bandwidth and energy inefficient. Hence, optical data interconnect platforms have begun to transition or extend from long distance or long-haul communications to ultra-short reach (<100 m) and even to inter-chip and possibly intra-chip distances in the order of centimeters or less. Recently, Cloud computing, Cloud Storage and exascale high performance computing at data centers with data storage and data communication infrastructures employing optical interconnect (OI) in ultra-short-reach regime have begun to play a key role to address the need of the Big Data era. The key to the wide-spread deployment of such OI infrastructure and platform is to lower the cost for manufacturing such optical data interconnect platforms. The cost for OI platforms and components can be reduced by optoelectronic multifunctional integration on silicon. A key component of such OI platforms is the high speed active optical cable (AOC) that connects the backplane of servers and computers at data centers. The key function for the AOC is to provide high capacity optical data transmission in terms of speed, energy efficiency and reliability with low manufacturing cost.

Silicon (Si) photonics has emerged in recent years as a viable platform for OI to address the need of the Big Data communications. The high index contrast of Si and SiO₂ allows ultra-high density integration of Si waveguide on a chip. Si-photonics built on silicon-on-insulator (SOI) substrate allows co-integration of SOI-based Si-photonic waveguide and CMOS electronics, thereby lowering the cost of manufacturing such OI infrastructure by leveraging on the existing low-cost and large scale CMOS manufacturing capability.

AOCs consist of optical fiber-to-chip with integrated optoelectronic transceivers on the chip. The key components in the AOC are the integrated transmitters on Si-photonic chip. Transmitters function to perform electrical to optical conversion of the digital data imparting it into guided laser beam in Si waveguide. For most suppliers of AOC, the integrated optoelectronic transceivers employ SOI-based modulators, which act as high speed optical shutters on guided laser beam in the SOI based Si-waveguide. The laser beam comes from a discrete laser diode flip-chip bonded to the Si-photonic transceiver chip. High capacity transmission AOC requires the implementation of wavelength division multiplexing (WDM) based laser light source. That is, laser beams of various wavelengths with each laser-wavelength being carrier for multi-gigabits/sec data rate. Due to the discrete nature, flip-chip bonded laser light cannot scale up in capacity in terms for WDM implementation. Therefore, there is a need for a scalable laser diode.

AOC may be capable of Terabits/sec data stream capacity employing WDM integrated transceiver built on Si-photonic platform. Various device structures may be available to produce variable wavelength on-chip WDM-light source, such as micro-ring, micro-disk and grating-based laser diodes. Semiconductor micro-disk laser has limited output power. The wavelength selection of the laser diode may be strongly dependent on fabrication variations, making wavelength targeting a big challenge.

Prior art optical devices may include heterogeneous III-V on SOI distributed feedback (DFB) lasers and distributed Bragg reflector (DBR) based lasers. An optically pumped membrane III-V on SOI DFB laser may have a low maximum output power of 125 nW. Electrically pumped hybrid III-V on SOI DFB and DBR laser diodes may be operated at continuous wave up to a maximum temperature of 50° C. and with a single wavelength emission of 1.6 μm with a maximum output power of 5.4 mW at 10° C. A prior art DBR laser may allow longer cavity length, and hence, may provide a higher output power and a lower device thermal impedance. A prior art hybrid III-V on SOI DBR laser may demonstrate continuous wave operation at emission wavelength of 1597.5 nm and may give a maximum output power of 11 mW at 15° C. The maximum operating temperature may be 45° C. These grating-based laser diodes may be built on the hybrid III-V on SOI evanescent device platform. In this platform, the thickness of the SOI may be about 0.7 μm, with AlGaInAs Multiple-quantum-well (MQW) directly bonded to SOI via plasma activated bonding surfaces. The AlGaInAs-MQW may provide the optical gain. The optical confinement factors in the AlGaInAs MQW active region and Si may be 5.2% and 59.2%, respectively. In this evanescent device platform, large optical confinement may be in the SOI and only a small percent of the optical mode may be in the AlGaInAs-MQW. In this configuration, the modal gain (Fg) may be small. A prior art hybrid III-V on SOI 360 μm-long DFB diode laser may have a shallow grating of 25 nm-depth partially etched into the SOI. Upon III-V epitaxy bonding on the SOI, the DFB laser may have grating embedded in the SOI with a grating coupling coefficient of K-247cm⁻¹. A prior art DBR laser may utilize a similar grating with a depth of 25 nm and may have a passive grating strength of lc: 73-80 cm⁻¹. In an evanescent platform, optical confinement factor in the SOI may be large and K may be sensitive to the grating depth. As the optical mode may have high confinement factor in the SOI, the SOI may need to be thick, for example about 700 nm in thickness. However, such a thick SOI may not be compatible with a Si-photonic modulator. A Si-photonic modulator may require a thinner SOI of less than 500 nm. The evanescent structure may have the disadvantage that only the evanescent tail experiences optical gain. Thick SOI may be used in these works because of the trade-off of modal gain in the III-V/Si with the III-V to Si output coupling efficiency. To improve modal gain, an alternative approach may be to use thinner SOI of less than 500 nm. In a thin-SOI hybrid III-V/SOI structure, optical confinement may be increased in the III-V layer. In contrast to the evanescent hybrid structure wherein the III-V ridge-width needs to be large to increase sufficient optical confinement in the III-V, for SOI thickness less than 500 nm, the width of the III-V ridge may be reduced to give a lower threshold current. For the thin SOI hybrid structure, the optical mode transfer coupler from III-V active layer to SOI layer may need to be carefully designed. Adiabatic mode transformers may be employed to ensure efficient optical mode coupling from the SOI layer to the III-V layer. The optical mode transfer from III-V to SOI or vice versa may be based on the optical super-mode transformation or optical up-down coupler. A prior art hybrid III-V on 500 nm-thick SOI Fabry-Perot (FP) LD may be used to perform pulsed or quasi-continuous wave lasing operation. The pulsed lasing may be attributed to the high contact resistance of 35Ω which may cause excessive thermal dissipation. A prior art heterogeneous III-V on thin SOI FP-LD (400nm-thick SOI) using a double taper optical up-down coupler may be used to provide continuous wave lasing operation for a threshold current of 30 mA, output power of 4 mW at room temperature, and maximum operating temperature up to 70° C. An 80 nm-thick of benzocyclobutene (BCB) bonding layer may be utilized between the III-V and the SOI. A prior art heterogeneous III-V on 400 nm-thick SOI DFB-LD may use a second order grating and may utilize a combination of CMP-thinned SiOx on SOI and BCB bonding layer. The thickness of the separation between the III-V and SOI may be about 110 nm. Since high optical confinement factor may lie in the III-V layer, the grating coupling coefficient may be nearly independent of the grating etch depth in contrast to the evanescent DFB.

In the context of various embodiments, “up-down coupler” may be but is not limited to being interchangeably referred to as “tapered end” or “nano-taper” or “up-down nano-taper”.

In the context of various embodiments, “P-contact” may be but is not limited to being interchangeably referred to as “P-metal”.

In the context of various embodiments, “N-contact” may be but is not limited to being interchangeably referred to as “N-metal”.

It should be appreciated and understood that the term “substantially” may include “exactly” and “similar” which is to an extent that it may be perceived as being “exact”. For illustration purposes only and not as a limiting example, the term “substantially” may be quantified as a variance of +/−5% from the exact or actual.

FIG. lA shows a schematic top view of a prior art optical device 100. The prior art optical device 100 may include a ridge waveguide 108 overlaid on a silicon-on-insulator (SOI) 102. The ridge waveguide 108 may include a III-V compound, in other words, a compound including at least one group III (IUPAC group 13) element and at least one group V (IUPAC group 15) element. The ridge waveguide 108 may be overlaid on a single-row grating 104 in the SOI 102. The single-row grating 104 may be positioned at a center of the SOI 102 and may be centered with respect to the III-V ridge waveguide 108. The single-row grating 104 may have a central grating width 122. The ridge waveguide 108 may include at least one up-down coupler 120 which may be tapered in shape. The up-down coupler 120 may be overlaid on a N-type indium phosphide (n-InP) layer 122. The optical device 100 may be representative of the optical devices in the prior arts, in that it consists of a single-row grating 104, in other words, a single section of grating. The prior art optical device 100 may be a heterogeneous III-V/SOI ridge waveguide used in a SOI distributed feedback (DFB) laser diode. The SOI 102 may have a thickness of about 300 nm. In the optical device 100, the cross-sectional optical mode profiles at the etched section of the grating 104 and at the unetched section of the grating 104 may be largely perturbed and sensitive to the grating depth. In order for the optical device to function properly, the lasing fundamental optical mode at the etched section of the grating 104 has to be matched to the lasing fundamental optical mode at the un-etched section of the grating 104. Mismatch of the fundamental modes between the cross-section of the etched section and the cross-section of the unetched section may result in scattering loss and degradation of the performance of the optical device 100.

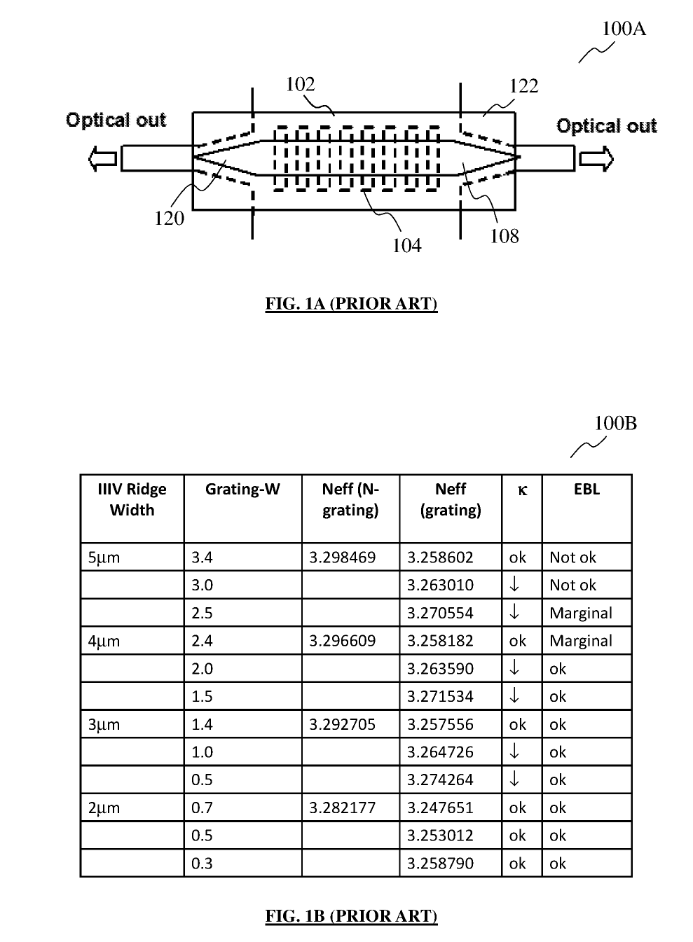

FIG. 1B shows a table 100B listing the limitations of the prior art optical device 100 of FIG. 1A. The table 100B includes a first column listing the III-V ridge width; a second column listing the central grating width; a third column listing the cross-sectional effective refractive indices of the un-etched region of the grating; a fourth column listing the cross-sectional effective refractive indices of the etched region of the grating; a fifth column indicating if the grating coupling coefficient is reduced; and a sixth column listing if the optical device 100 can be fabricated using e-beam lithography (EBL). The rows in the fifth column are indicated as “ok” when the grating coupling coefficient is not reduced, and indicated with a down-arrow to indicate that there is distortion in the optical mode in addition to the reduction in the coupling coefficient (κ). κ may be proportional to the index-contrast between the unetched and etched region of the grating. Therefore, as the central grating width 122 is reduced, the index-contrast is reduced and hence, κ is reduced. For a particular III-V ridge-width (first column), reducing the central grating width 122 (second column) may improve the manufacturability of the device (fifth column). i.e. grating can be printed by EBL without collapse of the grating patterns. However, this may result in distortion of the optical mode profile in the etched region of the grating while κ also reduces. Herein, lies the disadvantage of the central grating. The table 100B shows that if EBL were to be used to print the gratings of the prior art optical device 100, the III-V ridge width of the prior art device 100 has to be smaller than 3 μm or about 2 μm, so as not to have optical mode distortion as the central grating width 122 is reduced. The central grating width 122 may need to be varied for the purpose of tailoring the grating coupling coefficient of the prior art optical device 100.

An optical device according to various embodiments has a pair of symmetric side-gratings instead of a single-row grating, such that the fundamental optical modes at gratings cross-section has little mode-mismatch and the grating coupling coefficient κ is less sensitive to the grating etch-depth.

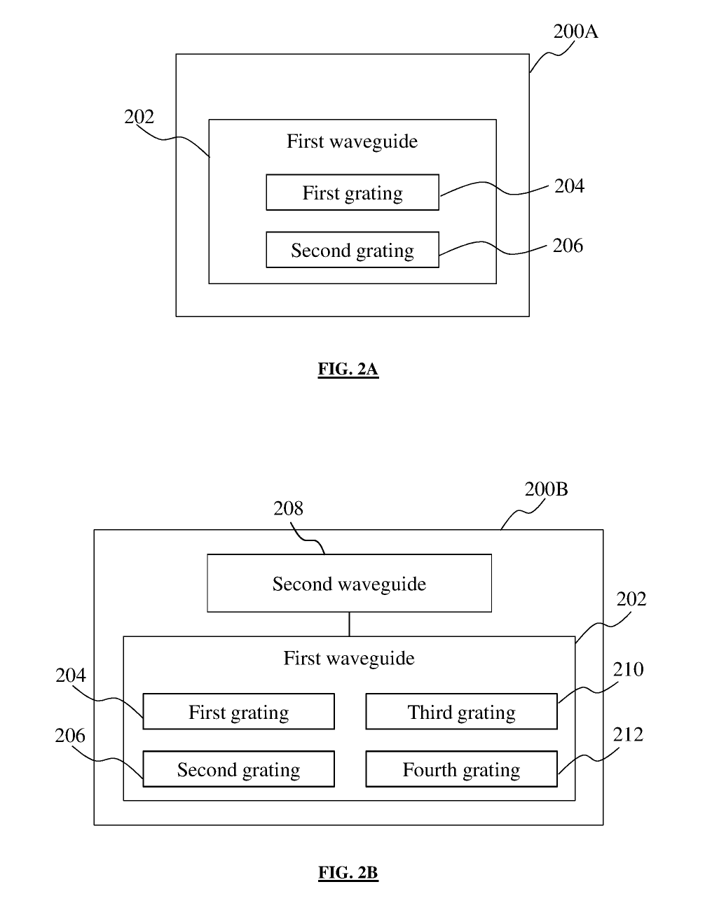

FIG. 2A shows a conceptual diagram of an optical device 200A according to various embodiments. The optical device 200 may include a first waveguide 202 configured to guide a light wave along a longitudinal axis. The optical device 200A may further include a first grating 204 and a second grating 206. The first grating 204 may be at least partially formed in the first waveguide 202 and the first grating 204 may be arranged away from the longitudinal axis in a first direction. The second grating 206 may be at least partially formed in the first waveguide 202 and the second grating 206 may be arranged away from the longitudinal axis in a second direction. The second direction may be different from the first direction.

In other words, according to various embodiments, an optical device 200A according to various embodiments may include a first waveguide 202, a first grating 204 and a second grating 206. The optical device 200 may be a laser diode. The optical device 200 may be a distributed feedback laser (DFB) or a distributed Bragg reflector (DBR). The first waveguide 202 may be configured to guide a light wave along a longitudinal axis. The first waveguide 202 may include silicon-on-insulator. The first grating 204 and the second grating 206 may be at least partially formed in the first waveguide 202, wherein the first grating 204 is positioned a first distance away from the longitudinal axis in a first direction and wherein the second grating 206 is positioned the first distance away from the longitudinal axis in a second direction. The second direction may be different from the first direction. The second direction may oppose the first direction, and each of the first direction and the second direction may be in a plane of the first waveguide 202 such that the longitudinal axis is between the first grating 204 and the second grating 206. The first grating 204 may include a first plurality of grating elements arranged in a first row, the first row being arranged at least substantially parallel to the longitudinal axis. The second grating 206 may include a second plurality of grating elements arranged in a second row, the second row being arranged at least substantially parallel to the longitudinal axis. Each grating element of one of the first plurality of grating elements or the second plurality of grating elements may be a groove etched into the first waveguide 202. The grating elements may be arranged such that a longest side of each grating element is at least substantially perpendicular to the longitudinal axis of the first waveguide 202. Each grating element of the second plurality of grating elements may mirror a respective grating element of the first plurality of grating elements, about the longitudinal axis. Each of the first grating 204 and the second grating 206 may include a plurality of periodically spaced grating elements. In other words, the spacing between every two grating elements of one of the first row or the second row, may be constant. The grating coupling coefficient of the optical device 200A may be dependent on the first distance.

FIG. 2B shows a conceptual diagram showing an optical device 200B according to various embodiments. The optical device 200B may include a first waveguide 202, a first grating 204 and a second grating 206 which may be at least substantially similar to the first waveguide 202, the first grating 204 and the second grating 206 of the optical device 200A of FIG. 2A. The first waveguide 202 may be configured to guide a light wave along a longitudinal axis. The first grating 204 may be at least partially formed in the first waveguide 202 and the first grating 204 may be arranged away from the longitudinal axis in a first direction. The second grating 206 may be at least partially formed in the first waveguide 202 and the second grating 206 may be arranged away from the longitudinal axis in a second direction. The second direction may be different from the first direction. The optical device 200B may further include a second waveguide 208, a third grating 210 and a fourth grating 212. The second waveguide may include a III-V semiconductor material. The second waveguide 208 may be arranged over the first waveguide 202 to at least partially overlap each of the first grating 204 and the second grating 206. The second waveguide 208 may also be arranged over the first waveguide 202 to at least partially overlap each of the first grating 204, the second grating 206, the third grating 210 and the fourth grating 212. The third grating 210 may be at least partially formed in the first waveguide 202 and may be arranged away from the longitudinal axis in the first direction. The fourth grating 212 may be at least partially formed in the first waveguide 202 and may be arranged away from the longitudinal axis in the second direction.

The first waveguide 202 may have a front end and a rear end, wherein the rear end opposes the front end. The first grating 204 and the second grating 206 may be arranged at the front end of the first waveguide 102 while the third grating 210 and the fourth grating 212 may be arranged at the rear end of the first waveguide 202. The portion of the second waveguide 208 at least partially overlapping the third grating 210 and the fourth grating 212 may be larger than another portion of the second waveguide 208 which at least partially overlaps the first grating 204 and the second grating 206. Each of the third grating 210 and the fourth grating 212 may be arranged at a second distance away from the longitudinal axis. The first distance may be larger than the second distance, vice-versa. Each of the third grating 210 and the fourth grating 212 may include more grating elements than each of the first grating 204 and the second grating 206, vice-versa. The central axis of the second waveguide 208 may be arranged in between the first grating 204 and the second grating 206. The central axis may also be arranged in between the third grating 210 and the fourth grating 212. The central axis of the second waveguide 208 may be equidistant from the first grating 204 and the second grating 206. The central axis may also be may be equidistant from the third grating 210 and the fourth grating 212. The second waveguide 208 may include at least one coupling end configured to couple the light wave between the first waveguide 202 and the second waveguide 208. The at least one coupling end may be tapered and may also include charge carriers such that the at least one coupling end is further configured to amplify the light wave.

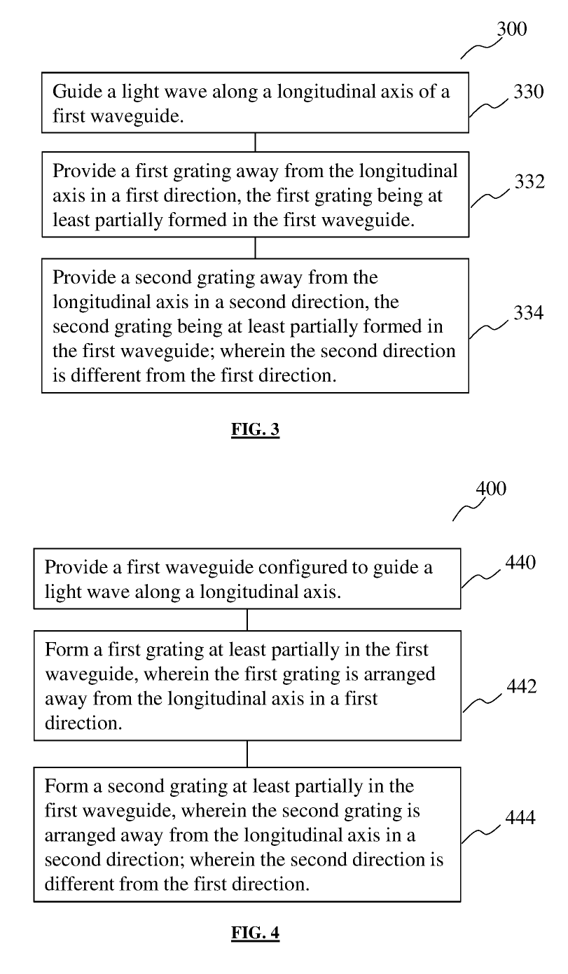

FIG. 3 shows a flow diagram 300 showing a method for providing a laser beam. In 302, a light wave is guided along a longitudinal axis of a first waveguide. In 304, a first grating is provided away from the longitudinal axis in a first direction, the first grating being at least partially formed in the first waveguide. In 306, a second grating is provided away from the longitudinal axis in a second direction, the second grating being at least partially formed in the first waveguide, wherein the second direction is different from the first direction.

FIG. 4 shows a flow diagram 300 showing a method for fabricating an optical device. In 402, a first waveguide is provided, the first waveguide being configured to guide a light wave along a longitudinal axis. In 404, a first grating is formed at least partially in the first waveguide, wherein the first grating is arranged away from the longitudinal axis in a first direction. In 406, a second grating is formed at least partially in the first waveguide, wherein the second grating is arranged away from the longitudinal axis in a second direction, wherein the second direction is different from the first direction.

An optical device according to various embodiments may be a laser diode. The laser diode may include a p-n diode with an active region where electrons and holes can recombine resulting in light emission. The laser diode may further include an optical cavity where stimulated emission can take place. The laser cavity may include a waveguide terminated on each end by a mirror. The mirror may be a grating that has a plurality of grating elements. The mirrors may reflect photons emitted into the waveguide, so that the photons may travel back and forth in the waveguide. The distance between the two mirrors is the cavity length. The laser diode may have a threshold current, which is the current for which the laser diode gain satisfies the lasing condition. The laser diode may emit very little light below the threshold current and therefore, a low threshold current is desirable.

An optical device according to various embodiments may be a non-evanescent heterogeneously bonded III-V on thin silicon-on-insulator (SOI) substrate distributed feedback (DFB) laser diode. The optical device may also be a distributed Bragg reflector (DBR) laser diode employing distributed Bragg gratings embedded in a SOI substrate, wherein the Bragg gratings include two rows of side gratings symmetrical with respect to the III-V ridge mesa of the laser diode. The optical device may be an integrated laser device on a Si-photonic chip capable of various emission wavelengths for WDM. The optical device may be used as an on-chip coherent light source for intra-chip and inter-chip optical interconnect applications.

According to various embodiments, an optical device may be fabricated by performing heterogeneous integration of III-V on SOI laser based on embedded grating. Wavelength emission may be based on periodicity of the embedded grating giving an increased wavelength targeting precision. In addition, grating-based laser diodes may have higher output power giving higher budget for longer optical reach and incorporation of passive or slightly absorptive components.

An optical device according to various embodiments, may include symmetric side gratings as compared to the conventional approach of using central grating as shown in FIG. 1A. The optical device may be one of a hybrid III-V on thin-SOI distributed Bragg grating (DBR) laser diode. The key advantage of the symmetric side grating is that it may result in less distortion or disruption to the propagating optical mode in the III-V ridge waveguide and may also provide good control of the DFB coupling coefficient (κ). For a thin-SOI hybrid III-V structure, the DFB coupling coefficient K may be highly sensitive to the etched depth of the grating for the central grating of the prior art optical device 100 of FIG. 1. The thermal impedance for a symmetric side grating structure may also be lower, as the grating trench poses less obstruction to the flow of heat from the III-V MQW active region to the bottom substrate, as compared to the central grating structure. This may be especially pronounced for broader III-V ridge waveguides having ridge widths beyond 2 μm.

An optical device according to various embodiments, may include a pair of symmetric side gratings. In contrast to a single row of grating placed on the central axis of the DFB laser diode, symmetric side gratings may be less disruptive to the propagating fundamental optical mode for thin-SOI. The symmetric side gratings may also achieve mode matching for the fundamental mode from a region of low refractive index to a region of high refractive index, independent of the thickness of the SOI. In an optical device with a single row of central grating, the fundamental single-lobe propagating mode profile degrades to a higher order dual-lobe mode as the light wave travels from a region of low refractive index to a region of high refractive index, when the central grating transverse width is not sufficiently large for a SOI thickness of 300 nm, although this may not happen when the SOI thickness is 220 nm. Even for a sufficiently large transverse width of the central grating, the coupling coefficient (κ) may be sensitive to variations in the grating etched depth ΔW_{depth}. However, for symmetric side grating, κ may be less sensitive to ΔW_{depth}. Symmetric side grating may offer another significant parameter to control κ, in the form of W_{gap} which is the distance between the pair of symmetric gratings. As W_{gap} can be defined by lithography, it may serve as a useful parameter for controlling κ. Hence, for symmetric side gratings, κ may be less sensitive to the etched depth. The on-wafer yield of κ may no longer be determined by the statistical variation of the etched depth of the grating as in the case of central grating. Instead, the on-wafer yield of κ may be determined by the lithographically defined W_{gap}.

An optical device according to various embodiments may include first order symmetric side gratings. First order gratings may have the advantage of higher energy efficiency as compared to a second order grating, due to lower radiation loss in the gratings. Nevertheless, the optical device may also include second order symmetric side gratings.

An optical device according to various embodiments, may include a SOI that is thinner than present state-of-the-art laser diodes. The SOI of the optical device may be about 300 nm in thickness. The thinner SOI may provide a higher optical confinement in the III-V ridge waveguide, and, therefore, higher modal gain in the III-V ridge, and lower threshold current density. The limiting factor for a thin SOI is that if the SOI is too thin, the light coupling to the external optical fiber may have deteriorated efficiency. A Multi-layer SuperGRIN lens (MLS-GRIN) lens may be used to perform coupling of an external optical fiber to SOI silicon waveguide thickness of down to 260˜300 nm.

An optical device according to various embodiments, may include at least one tapered end configured to couple light between the SOI and the III-V ridge waveguide. The tapered end may also be referred herein as an up-down coupler. The tapered end may have a length of about 50 μm which may be among the shortest in the current state-of-the-art. Simulation has shown that it takes about 20˜25 μm for the light-wave to couple from SOI waveguide to III-V ridge waveguide. This short distance is partly due to the use of thin SOI thickness of 300 nm. In addition, in our structure, the taper is made active by carrier injection for optical gain. The optical gain enhances or exhibits faster up-coupling due to gain-guiding effect, and compensates for the optical loss due to up-down coupling. Active taper may be provided for by the un-etched n-InP protruding toward the taper tip but pull back from taper-tip by 20 μm to lessen light-wave oscillation.

A method for fabricating an optical device according to various embodiments, may include direct bonding of a hybrid III-V epitaxy on a Si-photonic SOI substrate. The method may further include providing embedded gratings in a SOI layer. The III-V epitaxy bonded on the SOI substrate may include a multiple quantum well (MQW) epitaxially grown on an indium phosphide (InP) substrate. The MQW may include AlGaInAs or GaInAsP. The MQW may be strained in the material to provide an appropriately high optical gain. The top surface of the III-V epitaxy may be bonded to the Si surface of the SOI substrate. The gratings may be first formed on the SOI substrate by lithography, followed by partial vertical side-wall etching of the SOI substrate. Thereafter, the III-V epitaxy may be bonded onto the SOI substrate followed by removal of the InP substrate. A III-V ridge waveguide structure may be formed aligned to the grating originally formed on the SOI substrate.

A method for fabricating an optical device according to various embodiments may begin with the preparation of SOI substrate by targeting and thinning to the thickness of 300 nm by a two-step dry thermal oxidation. In the last step of the dry oxidation, the thermal oxide is retained and not removed by dilute HF dip, so that the thermal oxide may function as the hard-mask. Metal marker or etched-markers may then be formed on the SOI substrate by E-beam lithography (EBL). For the case of etched markers, the thermal oxide and SOI may be etched by Inductive Coupled Plasma (ICP) etching. A chromium (Cr) hard mask may be deposited on the SOI substrate followed by a second EBL to form the Si waveguide and gratings. The Ebeam resist used may be poly(methylmethacrylate) (PMMA). Alternative ebeam lithography resist such as ZEP520, NEB22, and others may also be used. The pattern may then be transferred to the SOI substrate by dry etching of the Cr-hard-mask and ICP etching of the SiO₂/Si. Both the Si rib waveguide and the DFB gratings may be formed at the same time. After removal of the resist and the Cr, the Out-Gassing Channel (OGC) pattern by photolithography may be performed. The patterning may open up 8 μm×8 μm square holes on the SOI substrate. The SiO₂ hard-mask and SOI may be etched in the OGC holes until the buried oxide layer is reached.

Subsequently, SiO₂ hard-mask on the SOI substrate may be removed by dilute HF. Both the SOI and the III-V may be cleaned and placed into an O₂ plasma for surface activation. The III-V epitaxy substrate may be bonded junction down to the SOI substrate with the InP substrate backside facing upward. Pressure of 1.5 MPa may be applied to the III-V epitaxy placed on the SOI substrate in an evacuated oven at a temperature of 220° C. to 250° C. for a time period of about 18 to 20 hours. After the III-V epitaxy is bonded to the SOI substrate, the InP substrate is removed by wet etching. The wet etching self-stops on the p+InGaAs layer. P-metal (Ti/Pt/Au) may be blanket deposited on the bonded chip and the III-V ridge waveguide may be patterned by EBL using a hydrogen silsesquioxane (HSQ) resist. The HSQ and the P-Metal may be used as hard-mask for pattern transfer to form the III-V ridge waveguide. The P-metal may be etched in ICP using Cl₂/Ar chemistry. Then, the p+InGaAs and p-InP vertical side-wall dry etching can be performed by ICP using Cl₂/Ar/N₂ chemistry. The etching may stop just before the interface to the AlGaInAs-MQW is reached, leaving about 100 nm of p-InP. The remaining p-InP may then be removed by wet etching in dilute HCl which self-stops on the AlGaInAs interface of the MQW. The AlGaInAs-MQW may then be removed by H₂SO₄:H₂O₂:DI-water (1:1:10) which self-stops on the n-InP. The N-metal (AuGe/Ni/Au) may be built on the n-InP by the lift-off process. The devices may be sent for contact testing after rapid-thermal-annealing is completed. Subsequently, the whole device may be blanket deposited with bisbenzocyclotene (BCB) and vias may be opened in the BCB. Ti/Au probe-metal, with Au thickness in the order of 1 μm, may be deposited and lifted-off filling the via openings.

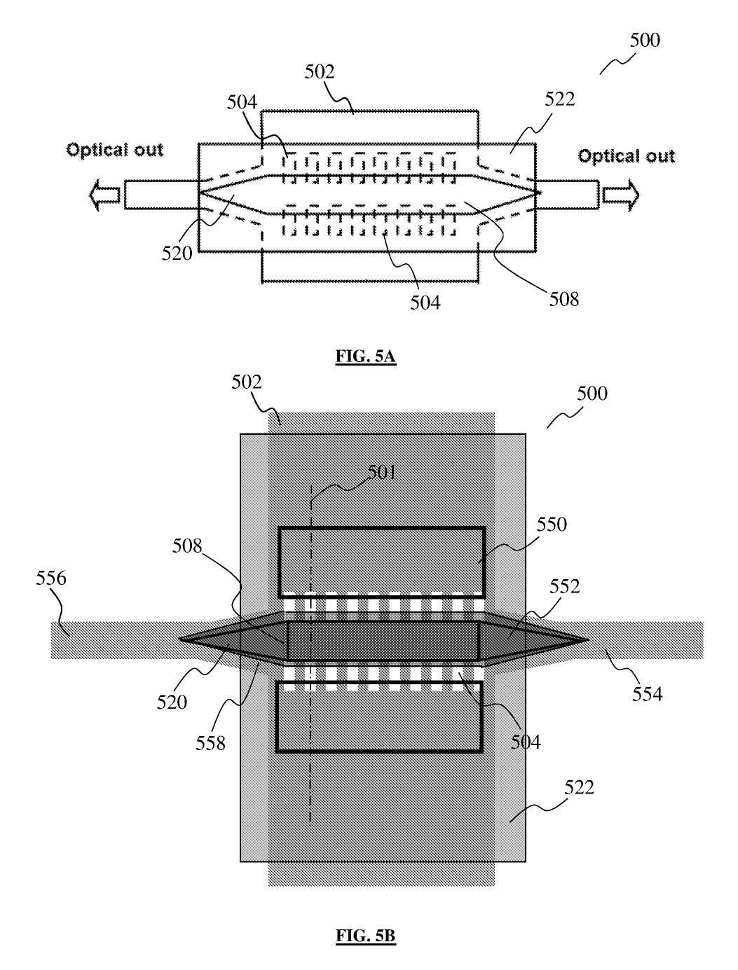

FIG. 5A shows a schematic plan view of an optical device 500, according to various embodiments. The optical device 500 may be identical to, or at least substantially similar to the optical device 200A of FIG. 2A or the optical device 200B of FIG. 2B. The optical device 500 may be a heterogeneous III-V on SOI DFB laser diode. The optical device 500 may include a SOI 502 arranged underneath an N-type InP (n-InP) layer 522. The SOI 502 may include two rows of side gratings 504 etched therein. The two rows of side gratings 504 may be arranged symmetric about a longitudinal axis of the SOI 502. The optical device 500 may further include a ridge waveguide 508 overlaid on the side gratings 504. The ridge waveguide 508 may include a III-V material. A central axis of the ridge waveguide 508 may coincide with a central axis in between the two rows of side gratings 504. The ridge waveguide 508 may include at least one tapered end 520. The tapered end may be configured to couple light from the SOI 502 to the ridge waveguide 508, as well as configured to couple light from the ridge waveguide 508 to the SOI 502.

FIG. 5B shows a schematic plan view of the optical device 500. The optical device 500 may include a SOI waveguide 554 formed as a part of the SOI 502. The SOI waveguide may include at least one end-polished facet 556. A P-contact 552 may be arranged over the ridge waveguide 508. At least one N-contact 550 may be arranged over the n-InP layer 522. The ridge waveguide 508 may be arranged over the SOI 502 such that the ridge waveguide at least partially overlaps the two rows of side gratings 504 formed in the SOI 502. The ridge waveguide 508 may include an active layer. The ridge waveguide 508 may further include a P-type InP (p-InP) layer 558 and a P++layer arranged over the active layer. A cross-sectional view of the optical device 500 may be provided along the line 501, to show the layers within the optical device 500.

FIG. 6 shows a schematic diagram 600 showing the cross-sectional view of the optical device 500 cut across the line 501. The ridge waveguide 508 may include an n-InP layer 522, at bonding layer 662, at least one N-contact 550, an active layer 660, a p-InP layer 558, a P++ InGaAs layer 668 and a P-contact 552. The active layer 660 may be arranged underneath the p-InP layer 558. The p-InP layer 558 may be arranged underneath the P++InGaAs layer 668. The P++InGaAs layer 668 may be arranged underneath the P-contact 552. The n-InP layer 522 maybe directly bonded to the SOI 502. The SOI 502 may be arranged over a buried oxide (BOX) layer 664. The BOX layer 664 may be arranged over a Si substrate 666. The active layer may include MQW and a layer of separate-confinement hetero-structure (SCH) over the MQW. The length of the side grating 504, also referred herein as a grating transverse length, may be denoted as L_{grating}. A depth of the side grating 504, also referred herein as the grating depth, may be denoted as W_{depth}. A distance between the two rows of side gratings 504, also referred herein as a grating gap, may be denoted as W_{gap}. A width of the ridge waveguide, also referred herein as the ridge width, may be denoted as Wᵣ. The bonding layer 662 may include benzocyclobutene (BCB). A method for fabricating the optical device 500 may be described in the following paragraphs.

A method for fabricating an optical device according to various embodiments may include patterning a SOI substrate. The SOI substrate may be deposited with a silicon oxide and chromium hard-mask, before being patterned by lithography so as to define a silicon waveguide and gratings. The waveguide and the gratings may be formed at the same time through the lithography. The lithography process may be one of projection mode photolithography or ebeam lithography. Ebeam lithography is most commonly used in the research and development environment as it is suitable for etching a small substrate suitable for device demonstration. Due to limitation of cell-size for ebeam writing which is typically 300 μm×300 μm or 600 μm×600 μm, careful attention needs to be taken at cell boundaries during device layout to reduce stitching errors. While a desired duty cycle of the grating may be 50%, the duty cycle may vary according to the dosage conditions of the ebeam exposure. The dosage of ebeam exposure may be optimized for achieving a desired grating duty cycle. For mass manufacturing environment, gratings are more commonly defined by laser interference photolithography. Both the waveguide and the gratings may be formed by partial etching into the SOI substrate. The SOI substrate may be about 300 nm in thickness. The waveguide comprises a rib structure, or a ridge structure. The waveguide and the gratings may be formed by partially etching the SOI substrate. The partial etching may be an etching of 240 nm into the SOI substrate. Alternatively, the grating depth may be varied and differed from a height of the ridge by using a separate mask to cover the grating section. The method may further include inductive-coupled plasma (ICP) etching with vertical side-walls in the silicon substrate. After forming the gratings and the ridge waveguide, the chromium hard mask may be removed from the silicon substrate by a liquid chromium etchant. The silicon oxide hard mask may be removed by wet etch in hydrofluoric acid (HF). The III-V epitaxy on InP substrate may be directly bonded on the SOI substrate by O₂-plasma activated bonding interfaces. The active layer which may include n-InP on AlGaInAs/InP MQW, may be bonded on the SOI substrate. Alternatively, the active layer may include GaInAsP-MQW. After bonding the active layer to the SOI substrate, the InP substrate may be removed by wet etch in dilute hydrochloric acid (HCl). The ridge waveguide may be formed over the SOI substrate with the ridge waveguide overlapping the embedded gratings. The ridge waveguide central axis may be in alignment with the central axis of the symmetric gratings.

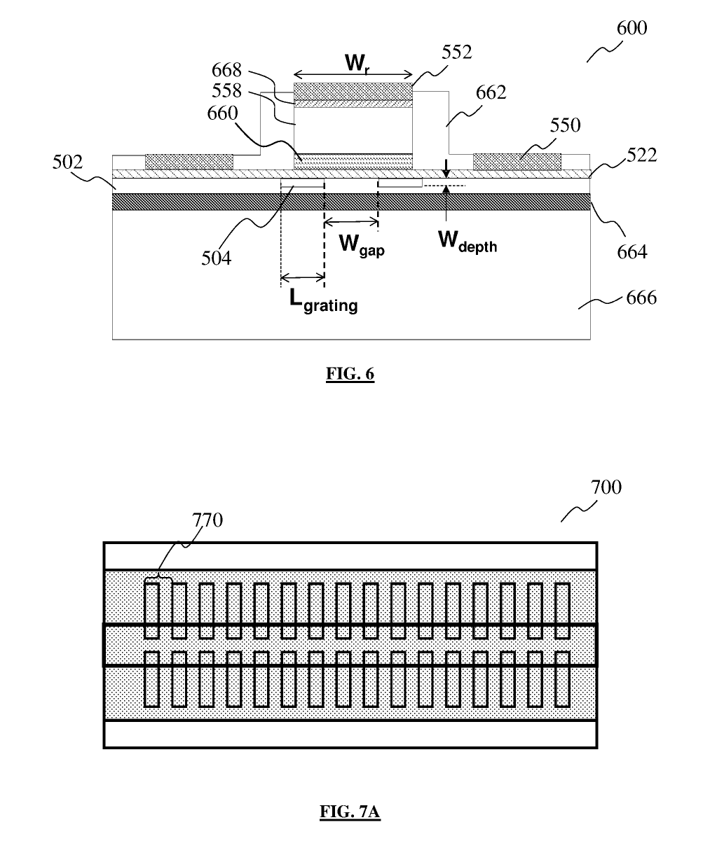

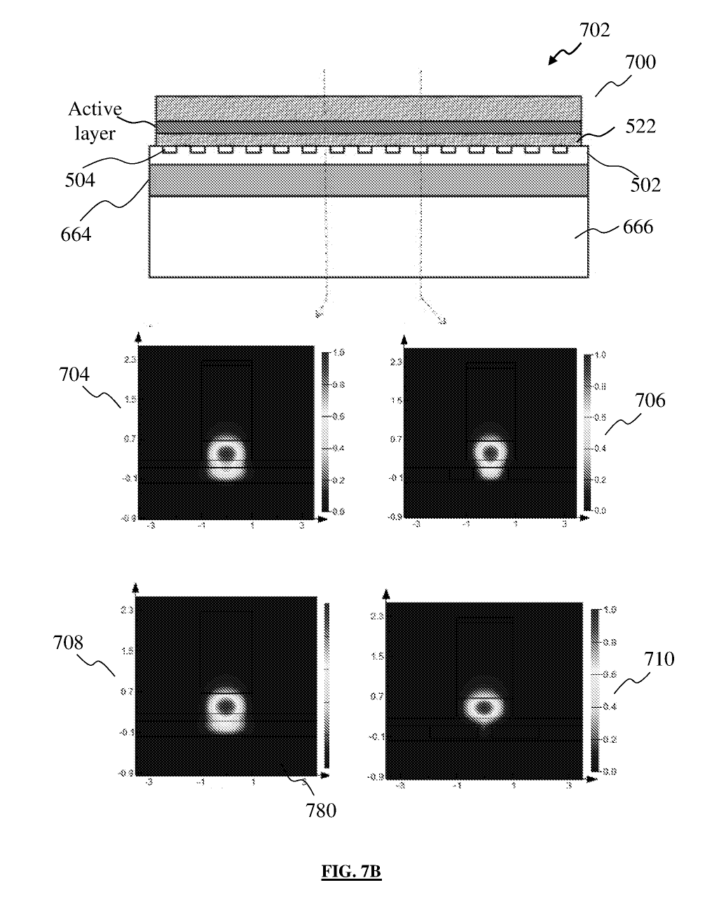

FIG. 7A shows a top schematic view of an optical device 700, according to various embodiments. The optical device 700 may include a pair of gratings partially etched into a SOI substrate. Each grating of the pair of gratings may include a plurality of grating elements arranged into a row. The pair of gratings may be symmetric about a longitudinal axis of the SOI substrate and the SOI substrate may include a waveguide configured to direct light to travel at least substantially along the longitudinal axis. The distance between any two grating elements of each row may be the same. The width of the grating element may be the same as the distance between any two grating elements. In other words, the duty cycle of the grating may be 50%. The grating period 770 may be about 235 nm to 240 nm.

FIG. 7B shows a schematic diagram 702, a first optical mode profile diagram 704, a second optical mode profile diagram 706, a third optical mode profile diagram 708 and a fourth optical mode profile diagram 710. The schematic diagram 702 shows a longitudinal cross-sectional view of the optical device 700 according to various embodiments. The optical device 700 may be similar or identical to the optical device 500 of FIG. 5. The optical device 700 may include a typical 2 μm-wide III-V ridge waveguide. The optical device 700 may be a DFB laser diode. Each of the first optical mode profile diagram 704, the second optical mode profile diagram 706, the third optical mode profile diagram 708 and the fourth optical mode profile diagram 710 includes a vertical axis indicating the vertical distance z in microns; and a horizontal axis indicating the horizontal distance y in microns.

The first optical mode profile diagram 704 and the second optical mode profile diagram 706 show the optical mode profile of the optical device 700 wherein the width gap is 0.8 μm. The first optical mode profile diagram 704 shows the optical mode profile at an unetched section of the grating of the optical device 700 while the second optical mode profile diagram 706 shows the optical mode profile at an etched section of the grating of the optical device 700. The second optical mode profile diagram 706 shows that the symmetric side grating of the optical device 500 perturbs the optical mode from the side. The third optical mode profile diagram 708 and the fourth optical mode profile diagram 710 show the optical mode profile of the optical device 700 wherein the width gap is 0.5 μm. The third optical mode profile diagram 708 shows the optical mode profile at an unetched section of the grating of the optical device 700 while the fourth optical mode profile diagram 710 shows the optical mode profile at an etched section of the grating of the optical device 700. As can be seen from FIG. 7B, the optical mode profile in the fourth optical mode profile diagram 710 remains as single lobe with the optical mode maxima remaining at the centre of the mode profile, even when the central grating gap width is reduced to an extremely small value of 0.5 μm. Hence, mode matching to the unetched region mode profile in the third optical mode profile 708 remains intact for a wide range of K. This is advantageous to the device designer.

The effective refractive indices for an unetched section of the grating and an etched section of the grating can be calculated by Film Mode Matching (FMM) or 2D-Finite Difference Method. The difference in the effective refractive indices can be used to calculate the grating coupling coefficient, κ. The calculated effective refractive index for 704 is 3.279, the calculated effective refractive index for 706 is 3.269, the calculated effective refractive index for 708 is 3.24496 and the calculated effective refractive index for 710 is 3.28218.

The grating coupling coefficient can be calculated by Equation (1):

$$κ = \frac{2 ( {n}_{eff}^{h} - {n}_{eff}^{l} )}{{λ}_{o}} \cdot sin ( m π \frac{{l}_{h}}{Λ} ) \qquad ( 1 )$$

where n^{h}_{eff} is the effective refractive index of the propagating optical mode in the unetched section of the grating and n^{l}_{eff} is the effective refractive index of the etched section of the grating.

Alternatively, the coupling coefficient can be calculated by means of the more fundamental expression in Equation (2):

$$κ = \frac{{ω}_{b}^{2}}{2 {c}^{2} {β}_{b}} \frac{\int \int Δɛ . {E}_{T} ( x , y ) dxdy}{\int \int {E}_{T} ( x , y ) dxdy} \qquad ( 2 )$$

where, Δε is the change in dielectric constant from section of high refractive index to section of low refractive index in the DFB grating, E_{T}(x,y) is the transverse electric field, c is the speed of light, ω_{b} is the Bragg frequency and β_{b} is the wave-number.

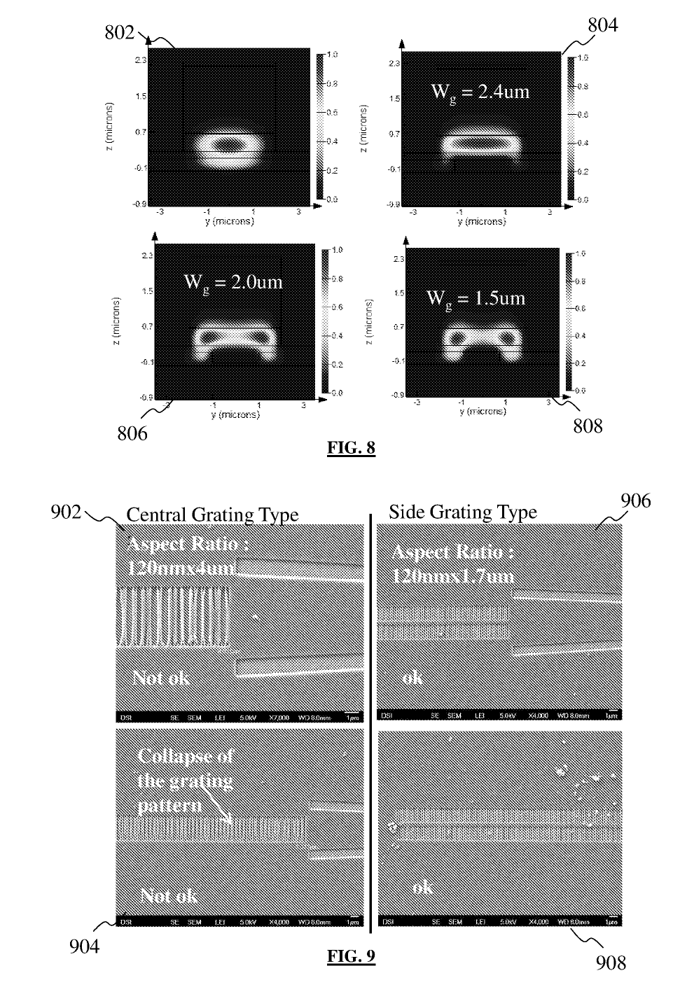

FIG. 8 shows four optical mode profile diagrams 802, 804, 806 and 808 of a prior art optical device similar to the prior art optical device 100 of FIG. 1A. The prior art optical device may have only a single row of gratings centered in the optical device. The prior art optical device may be a III-V/thin-SOI central grating DFB laser diode. The III-V ridge width may be about 4 μm while the SOI thickness may be about 0.3 μm. Each of the optical mode profile diagrams 802, 804, 806 and 808 shows an optical mode profile at the un-etched cross-section of the grating, wherein the central width of the prior art optical device is in a decreasing order from 802 to 808. As can be seen from FIG. 8, as the central grating gap width is reduced, the optical mode profile distorts into two lobes for a central grating gap width of less than 2 μm. This may cause poor matching of optical modes from unetched to etched regions.

FIG. 9 shows four scanning electron microscope (SEM) images 902, 904, 906 and 908. The SEM image 902 and the SEM image 904 show SEM images of the prior art optical device 100 of FIG. lA which has a single central row of grating, manufactured using EBL. The SEM image 906 and the SEM image 908 show SEM images of an optical device having two rows of symmetric side gratings, according to various embodiments, manufactured using EBL. The SEM images 906 and 908 show the typical EBL resist patterns of symmetric side gratings. The SEM images 902 and 904 show that the central grating EBL resist may tend to collapse as the central grating width is increased. The collapse of the resist may be due to the capillary force between the nanometer size resist strips of the grating pattern. The SEM images 906 and 908 show that for the optical device with two rows of symmetric side gratings, since the side gratings used a smaller aspect ratio of length and width, the resist is less likely to collapse. No collapse of the resist was observed in the practical devices used for demonstrating the feasibility of the optical device having two symmetric side gratings. The symmetric side grating has the advantage of no resist collapse while providing the flexibility in designing the device for targeting the desired κ.

FIG. 10 shows a graph 1000 showing the relationship of grating coupling coefficient κ with the grating gap width W_{gap}, for various III-V ridge widths at a grating etch-depth of 240 nm, for an optical device according to various embodiments. The graph 1000 includes a vertical axis 1002 indicating the grating coupling coefficient κ in cm⁻¹ and a horizontal axis 1004 indicating the grating gap width W_{gap} in μm. The graph 900 includes a first plot 1006 when the ridge width is 2 μm and the grating transverse length L_{g} is 1 μm; a second plot 1008 when the ridge width is 3 μm and L_{g} is 1 μm; a third plot 1010 when the ridge width is 4 μm and L_{g} is 1.7 μm; a fourth plot 91012 when the ridge width is 4 μm and L_{g} is 1 μm; and a fifth plot 1014 when the ridge width is 2 μm and computed using Equation (1). The degree of perturbation on the propagating optical mode of an optical device may be determined based on the grating gap width. Therefore, the grating gap width may determine the coupling coefficient of the grating. The graph 1000 shows that in general, the coupling coefficient κ decreases as W_{gap} increases. In addition, a laser diode structure with the smallest III-V ridge width may be most sensitive to the W_{gap}. The graph 1000 also shows that the region of interest 1016 for the κ value of the optical device may have a range of 100-200 cm⁻¹. The maximum possible κ may be achieved with a grating gap width of about 0.4 μm to 0.5 μm. To maintain κ˜110 cm⁻¹, W_{gap} may be chosen to be 1.4 μm, 1.7 μm, 2.0 μm, 2.2 μm for III-V ridge width of 2 μm, 3 μm, 4 μm, and 5 μm, respectively. The optical device used for demonstration may have a grating gap width of 1.4 μm.

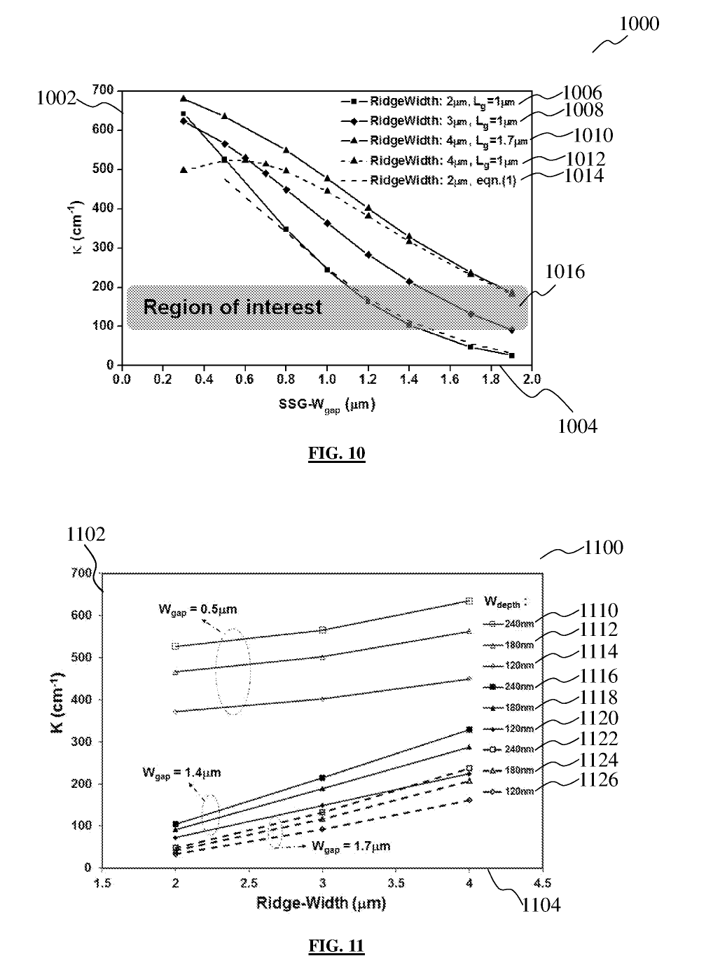

FIG. 11 shows a graph 1100 showing the relationship between coupling coefficient κ with III-V ridge width for various grating etch depths of 120 nm, 180 nm, and 240 nm, for W_{gap} of 0.5 μm, 1.4 μm and 1.7 μm, for an optical device according to various embodiments. The graph 1100 includes a vertical axis 1002 indicating the grating coupling coefficient κ in cm⁻¹ and a horizontal axis 1004 indicating the ridge width in μm. The graph 1100 includes a first plot 1110 when the width gap is 0.5 μm and the grating etch depth is 240 nm; a second plot 1112 when the width gap is 0.5 μm and the grating etch depth is 180 nm; a third plot 1114 when the width gap is 0.5 μm and the grating etch depth is 120 nm; a fourth plot 1116 when the width gap is 1.4 μm and the grating etch depth is 240 nm; a fifth plot 1118 when the width gap is 1.4 μm and the grating etch depth is 180 nm; a sixth plot 1020 when the width gap is 1.4 μm and the grating etch depth is 120 nm; a seventh plot 1022 when the width gap is 1.4 μm and the grating etch depth is 240 nm; an eighth plot 1024 when the width gap is 1.4 μm and the grating etch depth is 180 nm; and a ninth plot 1026 when the width gap is 1.4 μm and the grating etch depth is 120 nm. It can be observed from the graph 1100 that change in K with respect to the grating depth is the most sensitive when the grating gap W_{gap} is small. This is because for small grating gap, the optical mode field is strongly perturbed by the grating, and hence, most sensitive to the grating depth. For W_{gap} of 0.5 μm, the change in coupling coefficient (Δκ) is about 25˜30 cm⁻¹. For W_{gap} of 1.4 μm, Δκ is about 17 cm⁻¹, and for W_{gap} of 1.7 μm, Δκ is about 12 cm⁻¹. For a grating gap width of about 1.4 μm and 1.7 μm, κ may be less sensitive to the grating depth as compared to where the grating gap width is about 0.5 μm. For a change of grating depth of 120 nm, Δκ is about 164 cm⁻¹ where the gap width is 0.5 μm and the ridge width is about 3 μm. For a change of grating depth of 120 nm where the gap width is about 1.4 μm and the ridge width is about 3 μm, Δκ is about 66 cm⁻¹. For a change of grating depth of 120 nm where the gap width is about 1.7 μm and the ridge width is about 3 μm, Δκ is about 41 cm⁻¹.

According to various embodiments, the gratings used may be first order gratings. A typical grating period may be 240 nm with 50% duty cycle or fill-factor. In other words, the grating etch width may be about 120 nm. Second order gratings with grating period twice the physical dimension of the first order type may also be used in the optical device. Second order grating has the practical advantage of easier fabrication due to the larger grating period.

FIG. 12 shows a schematic top-down view 1200 of the gratings on an optical device according to various embodiments. The optical device may be a λ/4-shifted DFB laser diode, wherein the gratings are DFB gratings. The optical device may include two rows of gratings separated by a gap-width 1202. The grating phase at the center of the DFB grating may be shifted by π/2 in order to obtain a single wavelength emission. The λ/4-shifted first order grating is utilized for a demonstration device. The effective refractive indices of the un-etched and etched cross-sections in the DFB grating of the demonstration device are 3.2934 and 3.275, respectively.

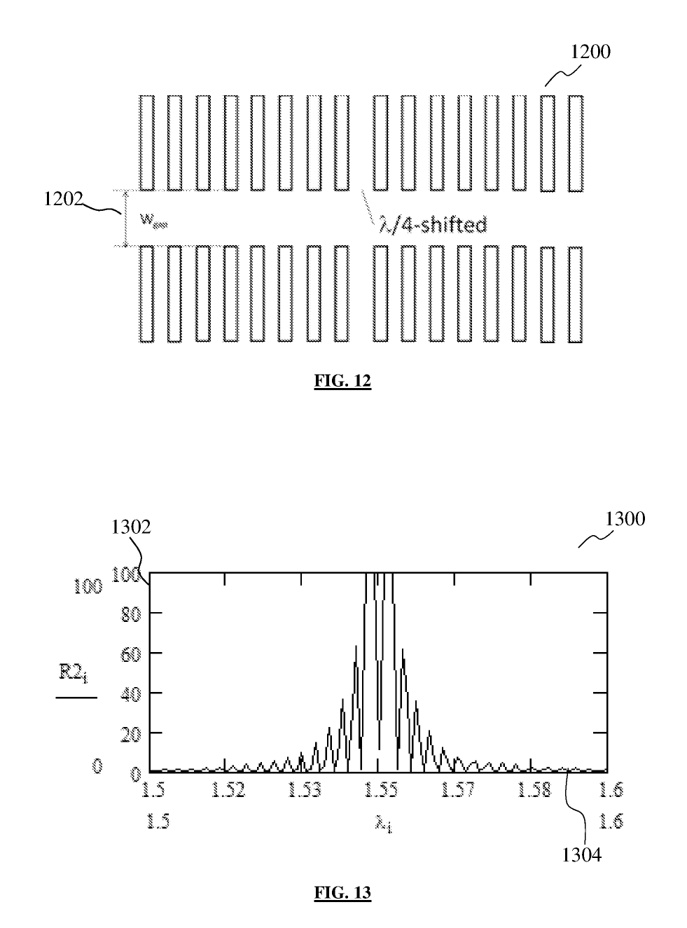

FIG. 13 shows a graph 1300 showing a reflection of the λ/4-shifted DFB grating plotted against a wavelength for the demonstration device. The ridge-width of the demonstration device is 4 μm and the grating duty cycle is 50%. The graph 1300 include a vertical axis 1302 indicating the reflection R2ᵢ; and a horizontal axis 1104 indicating wavelength λᵢ in microns. The graph 1300 is plotted based on the Transfer Matrix Method (TMM) for the case where there is no carrier injection. When carriers are injected into the active layer of the AlGaInAs MQW, there may be a gain in the DFB grating.

FIG. 14 shows a graph 1400showing a designed emission peak of the λ/4-shifted DFB grating. The ridge-width of the demonstration device is 4 μm and the DFB grating duty cycle is 50%. The designed emission peak is at 1550 nm. Based on this desired emission wavelength at 1550 nm and the effective refractive indices of the gratings, the calculated grating period is Λ=236 nm. For 50% duty cycle, half a period is 118 nm. In other words, the grating width will be 118 nm.

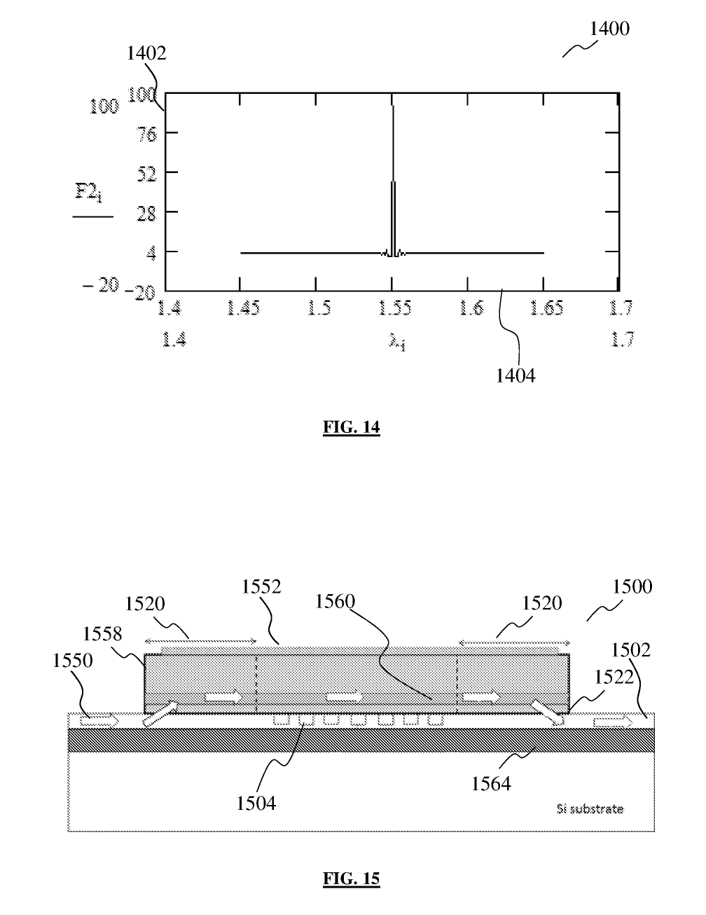

FIG. 15 shows a longitudinal cross-sectional view 1500 of an optical device according to various embodiments. The optical device may be a heterogeneous III-V on thin-SOI DFB laser diode. The optical device may include a SOI layer 1502 arranged over a buried oxide layer 1564 which is arranged over a silicon substrate. The SOI layer 1502 may be a first waveguide configured to propagate light along a longitudinal axis. The first waveguide may have two rows of side gratings 1504 etched therein. The optical device may further include a second waveguide arranged over the first waveguide such that the second waveguide at least partially overlaps the two rows of side gratings 1504. The second waveguide may be a III-V ridge waveguide. The second waveguide may include a n-InP layer 1522, an active layer 1560, a p-InP layer 1558 and a P-contact layer 1552. The cross-sectional view 1500 shows that the light wave 1550 propagates along a longitudinal axis in the first waveguide until it is coupled up to the second waveguide. The light wave 1550 then propagates along the longitudinal axis in the second waveguide until it is coupled down to the first waveguide. The propagating light wave 1550 may be coupled into the active layer 1560 through a nano-taper up-down coupler 1520. The active layer 1560 may include AlGaInAsInP-MQW. The light wave 1550 may experience optical gain before it is coupled down back into the first waveguide. In the demonstration device, the length of the nano-taper up-down coupler 1520 for one end is 50 μm.

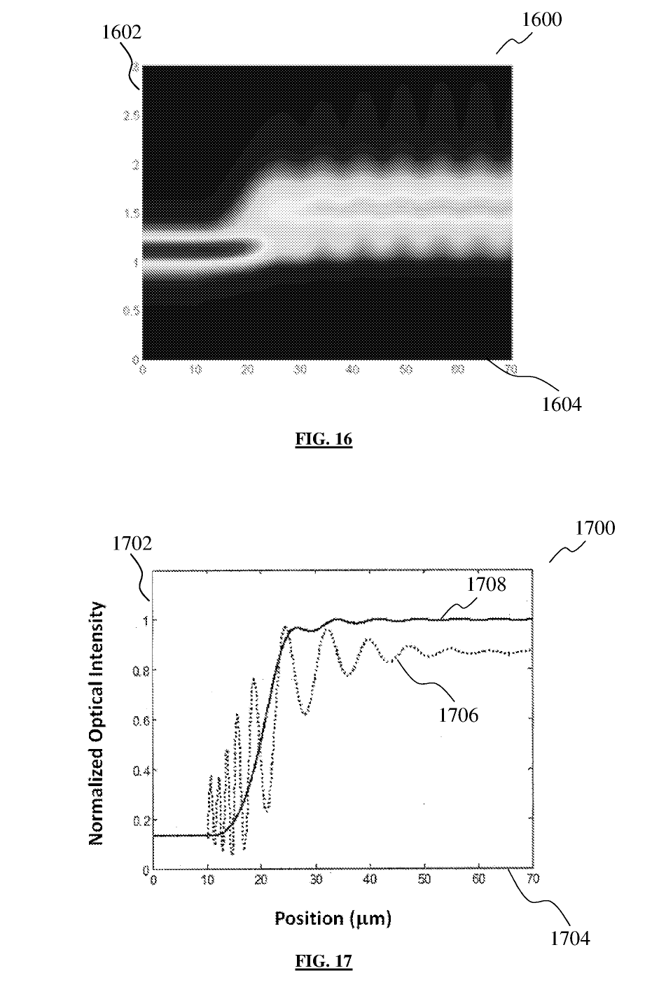

FIG. 16 shows a graph 1600 showing the 2-D Finite-Difference-Time-Domain (FDTD) simulation of the light-wave propagation in the nano-taper up-down coupler 1520 of FIG. 15. The graph 1600 includes a vertical axis 1602 indicating light intensity in arbitrary units (a.u.) and a horizontal axis 1604 indicating a position in μm. Light is completely coupled from a bottom of the SOI waveguide through the nano-taper up-down coupler, and finally along the III-V ridge waveguide. The SOI waveguide may be the first waveguide 202 of FIGS. 2A-2B and the III-V ridge waveguide may be the second waveguide 208 of FIG. 2B.

FIG. 17 shows a graph 1700 showing a normalized light intensity against a translational position on a SOI waveguide through a nano-taper up-down coupler, in an optical device according to various embodiments. The translational position is referenced from a point about 10 μm to the left from the tip of the up-down coupler on the SOI waveguide. The graph 1700 includes a vertical axis 1702 indicating the normalized optical intensity; and a horizontal axis 1704 indicating the translational position in μm. The graph 1700 includes a first plot 1706 and a second plot 1708. In a DFB laser diode, lasing oscillation may take place in the III-V ridge waveguide. By principle of reversibility, lasing light may couple from the III-V ridge waveguide into the SOI waveguide through the III-V taper up-down coupler. From the first plot 1706, it can be observed that the light wave takes about 20 μm to completely couple from the SOI waveguide into the III-V ridge waveguide. The up-down taper coupler exhibits optical loss, which should be minimized. Therefore, in the demonstration device, the taper is provided with an optical gain.

As shown in FIG. 15, the P-metal extends to the tip of the nano-taper. The P-metal may be overlaid with a dielectric layer. The dielectric layer may include hydrogen silsesquioxane (HSQ). The dielectric layer may be defined by EBeam lithography. The P-metal may function as the hard-mask for etching the III-V ridge waveguide and the nano-taper. To provide optical gain at the taper, carriers may be injected to reach into the MQW active layers in the nano-taper. To achieve carrier injection, the bottom n-InP must be present at the nano-taper tip for electron injection into the active layer of the taper. The n-InP layer outside the III-V ridge waveguide but atop the SOI waveguide must be etched to minimize optical loss.

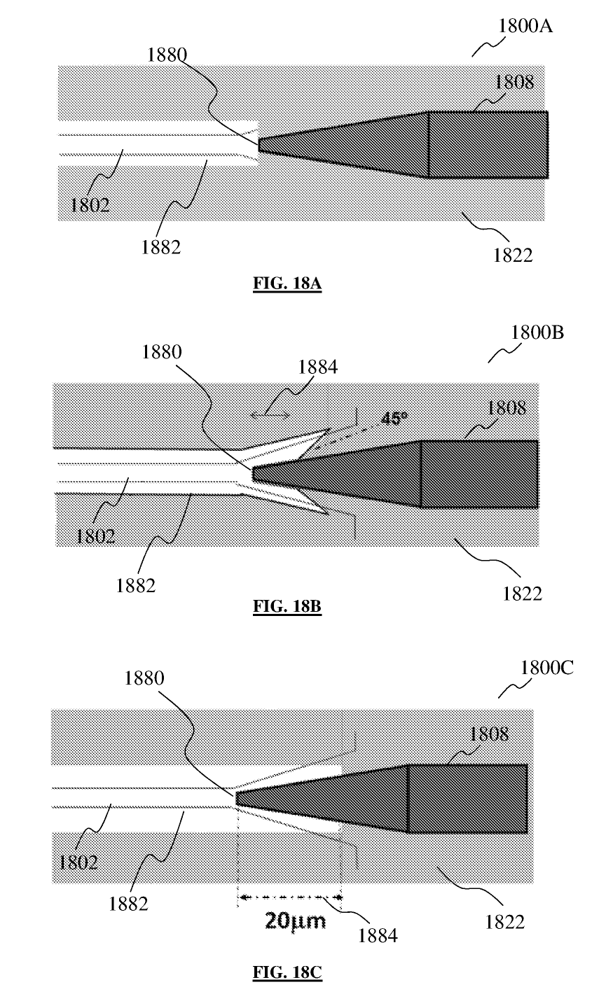

FIG. 18A shows a top view of an up-down coupler according to various embodiments. The up-down coupler may be a tapered end of a III-V ridge waveguide 1808. The up-down coupler may be configured to couple a light wave between a SOI waveguide 1802 and the III-V ridge waveguide 1808. The SOI waveguide 1802 may be arranged underneath an n-InP layer 1822 which may be etched away at 1882 to expose the SOI waveguide 1802. The n-InP layer 1822 may be etched away up to a tip 1880 of the tapered end. However, when the etched n-InP terminates right at the tip 1880 of the tapered end, up-down coupling of light-wave exhibited oscillation as simulated by 2D-FDTD and shown by the first plot 1706 in FIG. 17. The oscillation is due to the presence of n-InP at both sides of the tip 1880 that adds extra refractive index to the tip 1880 of the tapered end. The oscillation may be eliminated through a redesign of the tapered end, as shown in FIGS. 18B-18C.

FIG. 18B shows a top view of an up-down coupler according to various embodiments. The up-down coupler may be a tapered end of a III-V ridge waveguide 1808. Unlike the up-down coupler of FIG. 18A, the up-down coupler of FIG. 18B may have a coupling length 1884 of 20 μm, with the SOI waveguide 1802. In other words, the n-InP layer 1822 may be etched 20 μm beyond the tip 1880 of the tapered end. Since light takes about 20-25 μm to couple up into the III-V ridge waveguide 1808, the etched n-InP may be pushed back by 20 μm from the tip 1880 of the tapered end. Optical gain may be provided starting from where the light wave is coupled into the III-V ridge waveguide 1808 at the latter half of the tapered end. The un-etched n-InP layer 1822 can be about 45° away from the horizontal extending from 20 μμm away from the tip 1880. This is to provide a gradual change of the n-InP presence while providing n-type carrier injection.

FIG. 18C shows a top view of an up-down coupler according to various embodiments. The up-down coupler may be a tapered end of a III-V ridge waveguide 1808. Unlike in FIG. 18B, the n-InP layer 1822 may not be etched 45° away from the horizontal. In other words, the 45° wing in the n-InP structure of FIG. 18B may be omitted. The n-InP layer 1822 may still be etched 20 μm beyond the tip 1880 of the tapered end, such that the coupling length 1884 is still 20 μm. Simulation has shown that the structure shown in FIG. 18C wherein the rectangular n-InP is pushed back 20 μm has little optical oscillation in the up-coupling of light-wave. For the configurations of FIG. 18B and 18C, the 2D-FDTD results show that the oscillation in the light intensity at the nano-taper tip during up-down coupling is eliminated as shown by the second plot 1708 in the graph 1700 of FIG. 17.

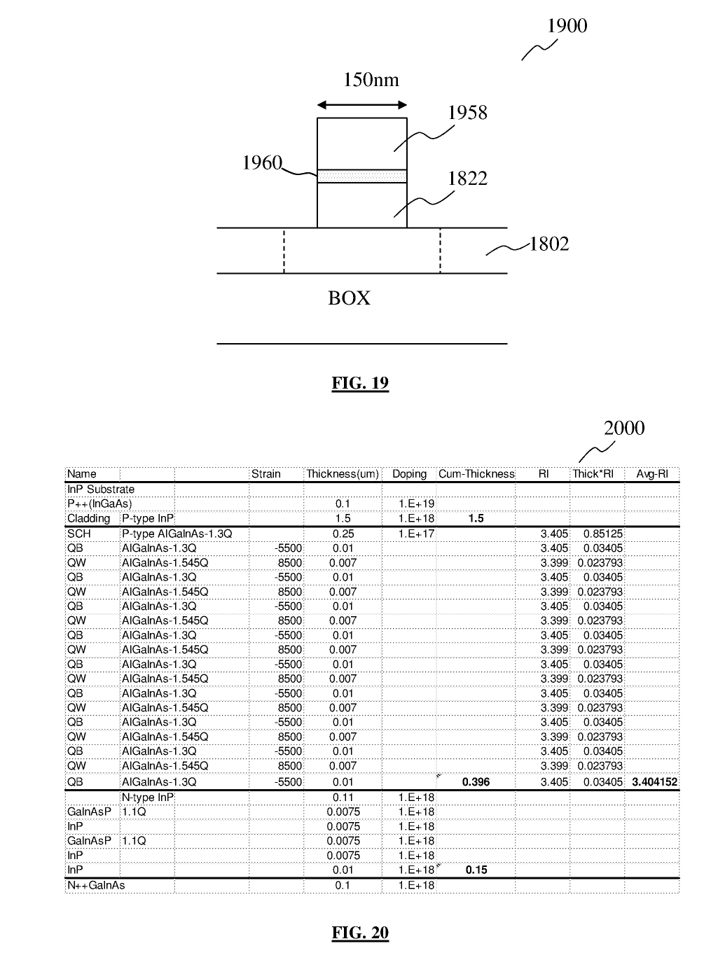

FIG. 19 shows a cross-sectional view 1900 at the tip 1880 of FIGS. 18A-18C. The tapered end of the III-V ridge waveguide may include an active layer 1960 sandwiched between a n-InP layer 1822 and a p-InP layer 1958. The ridge of the III-V ridge waveguide may be about 150 nm in width. The III-V ridge waveguide may be arranged over a SOI waveguide 1802. The SOI waveguide 1802 may be arranged over a buried oxide (BOX) layer.

FIG. 20 shows a table 2000 listing the epi-layers in a III-V epitaxy of an optical device according to various embodiments. The III-V epitaxy may be bonded to a SOI substrate. The III-V epitaxy may include a InP substrate at the top of the list. The III-V epitaxy structure may include AlGaInAs-MQW grown in the InP substrate. The III-V epitaxy may include a n-InP layer at the bottom and the n-InP layer may be directly bonded to the SOI substrate. The AlGaInAs-MQW may include 8 quantum-wells and each well of the 8 quantum wells may have a thickness of about 7 nm and a barrier of about 10 nm in thickness. A layer of separate-confinement hetero-structure (SCH) may be arranged over the AlGaInAs-MQW. The SCH may be configured to guide light waves. The n-InP layer may be embedded with two pairs of GaInAsP/InP superlattices. The two pairs of GaInAsP/InP superlattices may be configured to absorb dislocations resulting from the direct bonding, so as to prevent the dislocations from reaching the active layer and thereby degrading the active layer. The active layer may include the MQW and the SCH. The overall thickness of the active layer may be 0.396 μm or at least substantially equal to 0.4 μm. The average refractive index of the active core may be at least substantially equal to 3.4. The bottom-most layer may include N++InGaAs. The N++InGaAs layer may be usually removed by wet etching before the III-V epitaxy is bonded to the SOI substrate. The active layer including the MQW and SCH may be intrinsically un-doped whereas the n-InP layer and the p-InP may be doped to 1×10¹⁸cm⁻³. After the SOI waveguide, gratings and out-gassing channel patterns are defined on the SOI substrate, the SiOx hard-mask may be removed by dilute hydrofluoric acid. Both the III-V epitaxy and SOI surfaces may undergo O2-activation, before the III-V epitaxy may be bonded on the SOI substrate. The InP substrate at the top of the III-V epitaxy may be removed by wet chemical etching in dilute hydrochloric acid. After removal of the InP substrate, the total thickness of the remaining epitaxy may be about 2 μm. The DFB laser diode may then be built on the III-V epitaxy.

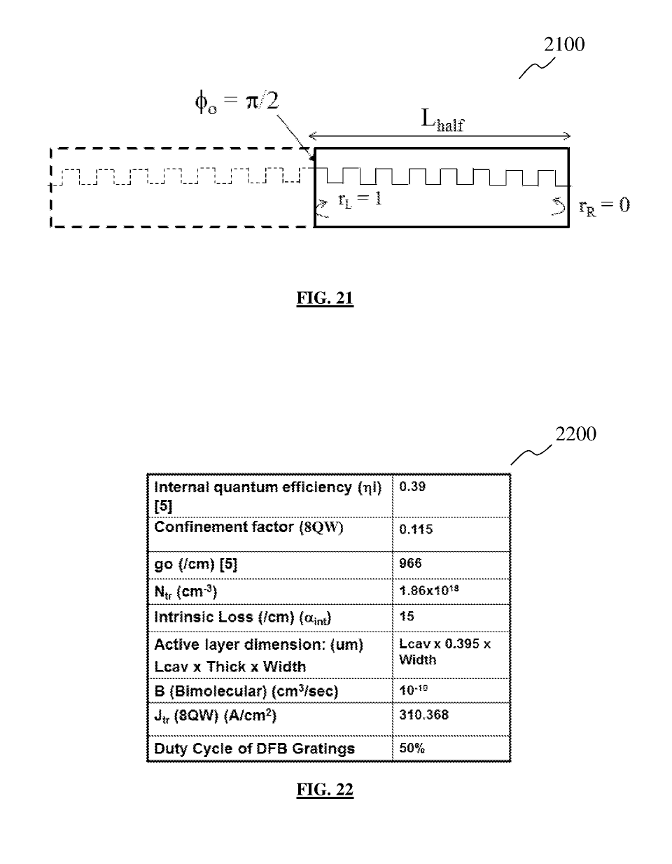

FIG. 21 shows a schematic diagram of an analytical model 2100 used to calculate the threshold gain of a λ/4 shifted DFB laser diode structure. The optimized cavity length for the lowest possible threshold current may be ascertained using the analytical model 2100. The left and right facet reflectances of the grating are denoted as r_{L} and r_{R} respectively. The phase shift of light wave at the origin of the horizontal axis is denoted as φₒ. The threshold condition equation of the λ/4-shifted DFB LD may be obtained where r_{L}=1 and r_{R}=0.0, so that the actual laser cavity length is 2×L_{half}. The whole laser cavity may be the result of perfect reflection at the left facet. For the λ/4-shifted DFB, the phase shift at the origin of the horizontal axis should be φₒ=π/2. Based on the coupled mode theory, from the coupled-mode equations, the characteristic equation on the threshold conditions can be derived and is given in Equation (3) as follows:

$$\frac{{γ}^{2}}{{sinh}^{2} ( γ {L}_{half} )} - 2 κ . {r}_{L} γ \frac{cosh ( γ {L}_{half} )}{sinh ( γ {L}_{half} )} + {κ}^{2} [ 1 + {r}_{L}^{2} ] = 0 \qquad Equation ( 3 )$$

In Equation (3), κ is the coupling coefficient of the grating and γ is the wave constant of the amplitudes of the forward and backward propagation EM waves in the cavity. The eigenvalue γ and κ are related by the dispersion relation,

γ²+κ²+(α−jδ)² Equation (4)

The threshold gain (α) and the corresponding phase constant detuning δ=(β−βBragg) can be determined if the eigenvalue γ is found in Equation (3). The threshold current for various cavity lengths may be calculated based on the diode laser physical and materials parameters stated in Table 2200 of FIG. 22.

FIG. 22 shows a Table 2200. The Table 2200 lists down the laser diode material and device parameters that may be used for calculating the threshold currents for various cavity lengths.

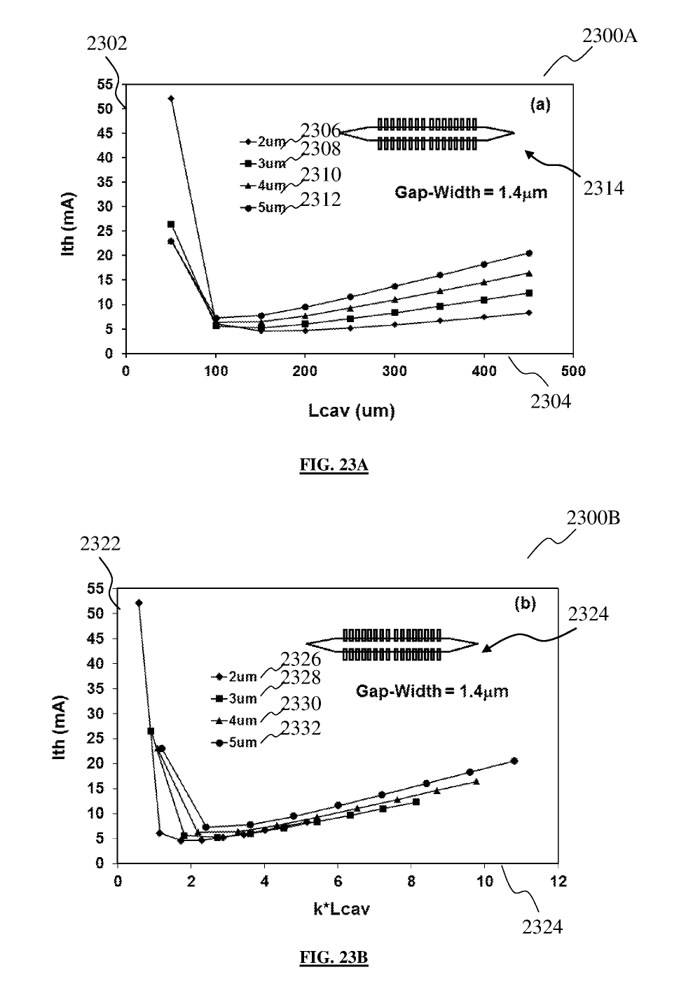

FIG. 23A shows a graph 2300A showing the threshold current Iₜₕ plotted against the cavity length L_{cav} of a λ/4-shifted DFB laser diode. The DFB laser diode may be a hybrid III-V on SOI DFB laser diode. The graph 2300A may be plotted based on the laser diode material and device parameters listed in Table 2200 of FIG. 22. The graph 2300A may include a vertical axis 2302 indicating Iₜₕ in milliamperes; and a horizontal axis 2304 indicating L_{cav} in micron. The λ/4-shifted DFB laser diode may have a π/2-phase shift section at the symmetric center of the cavity. The λ/4-shifted DFB laser diode may include two rows of symmetric side gratings. The gap width between the two rows of side gratings may be 1.4 μm. The DFB laser diode may include a III-V ridge waveguide arranged over a SOI waveguide. The graph 2300A includes a first plot 2306 for the case where the ridge width of the III-V ridge waveguide is 2 μm; a second plot 2308 for the case where the ridge width is 3 μm; a third plot 2310 for the case where the ridge width is 4 μm; and a fourth plot 2312 for the case where the ridge width is 5 μm. The inset 2314 shows a schematic top view of the laser diode with symmetric side gratings and with a λ/4-phase shift at the center.

FIG. 23B shows a graph 2300B showing threshold current plotted against the normalized coupling coefficient (κL_{cav}) for the λ/4-shifted DFB laser diode. These threshold currents were calculated based on the laser diode material and device parameters listed in Table 2200 of FIG. 22. The L_{cav} ranges from 50 μm to 500 μm. The graph 2300B includes a vertical axis 2322 indicating Iₜₕ in milliamperes and may further include a horizontal axis 2324 indicating κL, a product of the grating coupling coefficient with the cavity length. The graph 2300B further includes a first plot 2326 for the case where the ridge width of the III-V ridge waveguide is 2 μm; a second plot 2328 for the case where the ridge width is 3 μm; a third plot 2330 for the case where the ridge width is 4 μm; and a fourth plot 2332 for the case where the ridge width is 5 μm. The inset 2324 shows a top schematic view of a hybrid III-V on SOI DFB laser diode with symmetric side gratings and with λ/4-phase shift at the center. In the graphs 2300A and 2300B, the gap-width of the symmetric side gratings are kept constant at 1.4 μm. As shown in the graph 1000 of FIG. 10, the coupling coefficient κ increases in value with an increase in the ridge width, for a constant gap-width. The graph 2300A shows that for a ridge width of 2 μm, the L_{cav} corresponding to the lowest Iₜₕ ranges from 150 μm to 200 μm. As for ridge widths of 3 μm, 4 μm and 5 μm, the L_{cav} for the lowest Iₜₕ ranges from 100 μm to 150 μm. The Iₜₕ increases as the L_{cav} decreases beyond the optimal L_{cav}. This increase in Iₜₕ is the quickest for a 2 μm III-V ridge-width. This rate of increase in Iₜₕ with a decrease in L_{cav}, reduces with increasing ridge widths from 3 μm to 5 μm, due to the higher average (or un-perturbed) cavity effective refractive indices of the DFB for wider ridge-widths.

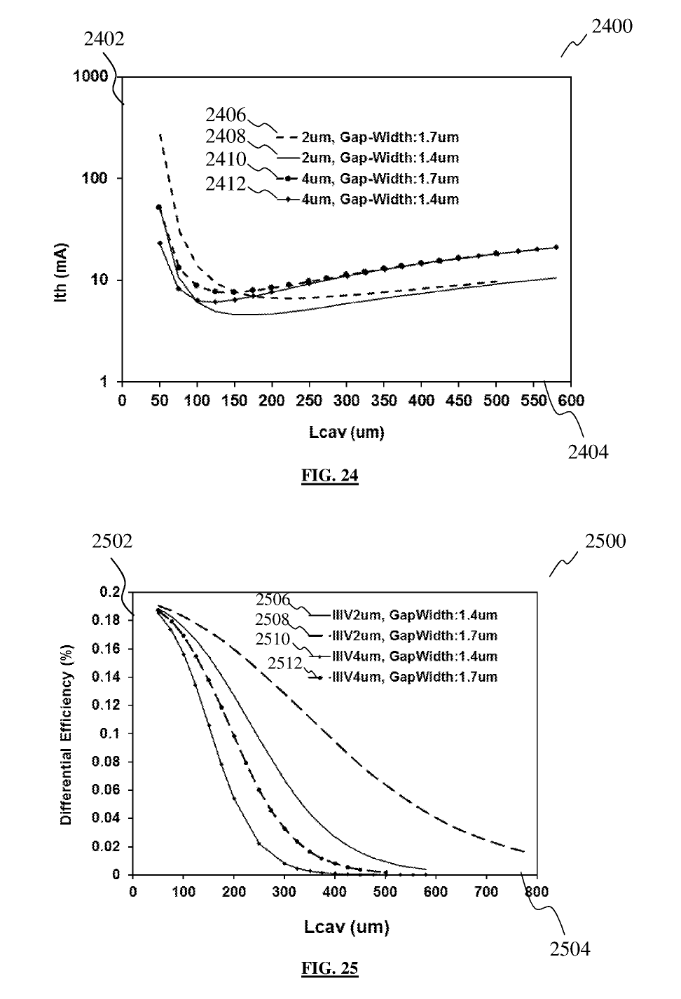

FIG. 24 shows a graph 2400 1showing the threshold current Iₜₕ plotted against cavity length L_{cav} of a λ/4-shifted DFB laser diode according to various embodiments. The laser diode may include a III-V ridge waveguide. The ridge width of the ridge waveguide may be one of 2 μm or 4 μm. The laser diode may include a pair of symmetric gratings. The gap width between the pair of symmetric gratings may be one of 1.4 μm or 1.7 μm. The graph 2400 includes a vertical axis 2402 indicating Iₜₕ in miliamperes; and a horizontal axis 2404 indicating L_{cav} in micron. The graph 2400 includes a first plot 2406 representing the plot for ridge-width of 2 μm and a grating gap-width of 1.7 μm; a second plot 2408 representing the plot for ridge-width of 2 um and a grating gap-width of 1.4 μm; a third plot 2410 representing the plot for ridge-width of 4 μm and a grating gap-width of 1.7 μm; and a fourth plot 2412 representing the plot for ridge-width of 4 μm and a grating gap-width of 1.4 μm. The graph 2400 shows the comparison of Iₜₕ between the cases of gap-widths of 1.4 μm and 1.7 μm. For the same ridge width, the Iₜₕ for different gap widths converge when L_{cav} is above 350 μm. While different gap widths should result in different values for the coupling coefficient κ, when L_{cav} is large, light may be confined within the DFB cavity irrespective of the coupling coefficient, therefore causing Iₜₕ to converge irrespective of the coupling coefficients when L_{cav} is large. Also, higher ridge-width may result in a larger carrier injection area and, hence, a larger threshold current. For the same III-V ridge width at the optimal L_{cav} range of about 100 μm-200 μm, a wider gap-width may result in a higher threshold current Iₜₕ due to a smaller coupling coefficient. This is because a higher coupling coefficient may provide a more localized optical feedback and hence, lower the threshold gain, and thereby lower the threshold current.

FIG. 25 shows a graph 2500 showing the differential quantum efficiency of an optical device according to various embodiments, plotted against the cavity length. The optical device may have a III-V ridge waveguide. The ridge waveguide may have a ridge width that is one of 2 μm or 4 μm. The optical device may have a pair of symmetric gratings formed therein. The optical device may be a λ/4-phase shifted DFB laser diode. The gap width between the pair of symmetric gratings may be one of 1.4μm or 1.7 μm. The graph 2500 includes a vertical axis 2502 indicating differential efficiency in percentage; and a horizontal axis 2504 indicating L_{cav} in p.m. The graph 2500 includes a first plot 2506 representing the plot when the ridge width is 2 μm and the gap width is 1.4 μm; a second plot 2508 representing the plot when the ridge width is 2 μm and the gap width is 1.7 μm; a third plot 2510 representing the plot when the ridge width is 4 μm and the gap width is 1.4 μm; and a fourth plot 2512 representing the plot when the ridge width is 4 um and the gap width is 1.7 μm. The differential efficiency may be based on one-sided output optical power from a symmetric λ/4-phase shifted DFB with phase shift at the center of the DFB cavity, and zero reflectivity at both output facets of the optical device. The graph 2500 shows that a larger gap width results in a lower coupling coefficient and a higher differential quantum efficiency. A smaller coupling coefficient means that the DFB localized feedback is smaller while the optical output at the end facet is higher. The graphs 2400 and 2500 show that the best differential efficiency and the lowest threshold current may be achievable with a cavity length at least substantially in the range of 100-200 μm.

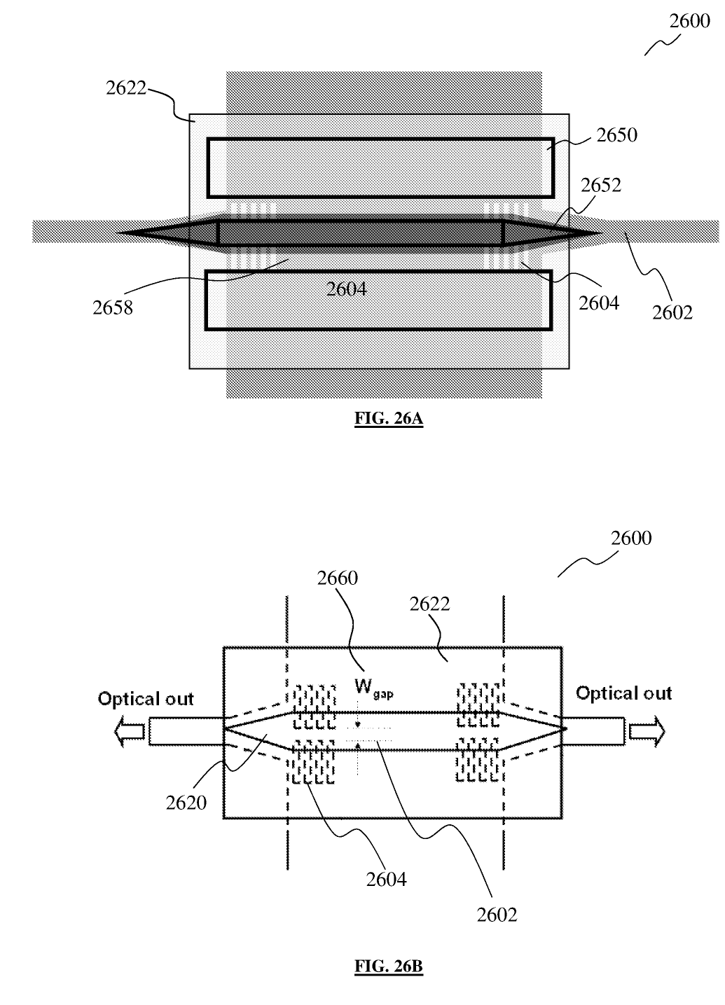

FIG. 26A shows a schematic top view diagram of an optical device 2600 according to various embodiments. The optical device 2600 may be a distributed Bragg reflector (DBR) laser diode. The optical device may be a heterogeneous III-V on thin-SOI distributed DBR laser diode or a laser diode using the side-gratings as DBR mirrors at front and back facets of the laser diode structure. The optical device 2600 may include a SOI waveguide 2602 formed out of a SOI substrate. The SOI waveguide 2602 may include two rows of gratings 2604, the two rows of gratings being arranged symmetric about a longitudinal axis of the SOI waveguide 2602. The optical device 2600 may further include an n-InP layer 2622 arranged over the SOI substrate and the SOI waveguide 2602. The optical device 2600 may further include a III-V ridge waveguide arranged over the gratings 2604. The structure of the gratings 2604 may be similar to the gratings 504 of FIG. 5 or the gratings 204 and 206 of FIG. 2A-2B. However, the gratings 2604 may include a first set arranged at a front facet of the optical device 2600; and a second set arranged at a rear facet of the optical device 2600. Each of the first set and the second set may include two rows of gratings arranged symmetric about the longitudinal axis. The optical device 2600 may further include at least one N-contact 2650 on the n-InP layer 2622; and a P-contact layer 2652 over a p-InP layer 2658. The p-InP layer 2658 may be arranged over an active layer of the III-V ridge waveguide.

FIG. 26B shows a top schematic view of the optical device 2600. The optical device 2600 may be a hybrid III-V on thin-SOI laser diode. The symmetric side gratings 2604 may serve as distributed Bragg mirrors. The first set of gratings at a front end of the SOI waveguide may be configured to function as a front mirror; while the second set of gratings at a rear end of the SOI waveguide may be configured to function as a rear mirror. Each of the first set of gratings and the second set of gratings may have a pair of gratings. Each grating of the pair of gratings may have a plurality of grating elements. Every grating element of a grating has a corresponding symmetric grating element in a further grating within the same set. Each grating element, together with its corresponding symmetric grating element, forms a DBR mirror pair. The optical device 2600 may employ a small W_{gap} to obtain a large grating coupling coefficient K for the DBR mirrors. W_{gap} refers to gap width 2660 which is the distance between the two gratings symmetric about the longitudinal axis. The first set of gratings may have a large W_{gap} and a small number of DBR mirror pairs while the second set of gratings may have a small W_{gap} and a large number of DBR mirror pairs to obtain a single-ended optical power output from the front and almost 99% reflection at the rear. In comparison, conventional DBR LD, single row of grating may be placed at the center of the laser cavity, similar to the optical device 100 of FIG. 1.

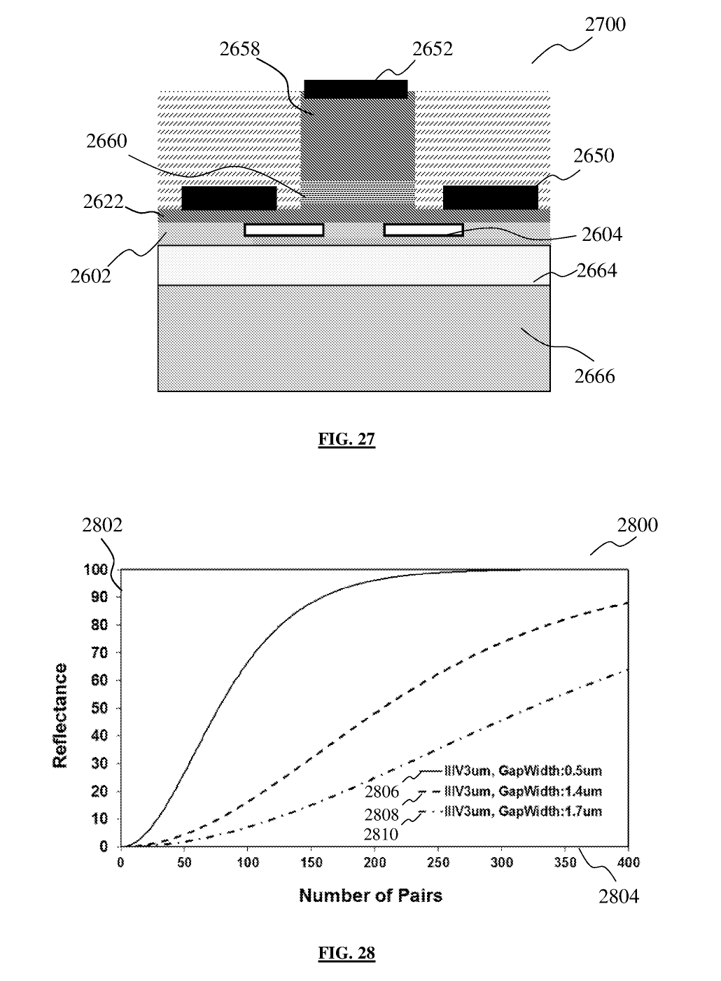

FIG. 27 shows a cross-sectional view 2700 of the optical device 2600 of FIG. 26A, cut along an axis perpendicular to the longitudinal axis. The cross-sectional view 2700 may be similar to the cross-sectional view 600 of the optical device 500. The optical device 2600 may include a silicon substrate 2666, an oxide layer 2664, a SOI waveguide 2602, a plurality of gratings 2604 formed at least partially in the SOI waveguide 2602, a n-InP layer 2622, at least one N-contact 2650, an active layer 2660, a p-InP layer 2658 and a P-contact 2652.

FIG. 28 shows a graph 2800 showing the DBR reflectance plotted against a number of mirror pairs for an optical device according to various embodiments. The values for plotting the graph 2800 may be computed using the transmission matrix method (TMM). The optical device may be at least substantially similar to the optical device 2600 of FIGS. 26-27. The optical device may include a III-V ridge waveguide having a ridge width of 3 μm. The optical device may include symmetric side gratings and the distance between a grating on a first side of the longitudinal axis of the SOI waveguide and another grating on a second side of the longitudinal axis, in other words, the gap width, may be one of 0.5 μm, 1.4 μm, or 1.7 μm. The graph 2800 includes a vertical axis 2802 indicating reflectance; and a horizontal axis 2804 indicating a number of DBR mirror pairs. The graph 2800 further includes a first plot 2806 representing the plot when the ridge with is 3 um and the gap width is 0.5 um; a second plot 2808 representing the plot when the ridge with is 3 um and the gap width is 1.4 um; and a third plot 2810 representing the plot when the ridge with is 3 um and the gap width is 1.7 um. All reflectances have been calculated for transverse-electric (TE) polarization. The reflectance may increase fastest for a smallest W_{gap} because the grating coupling coefficient κ is largest for a smallest W_{gap}. The W_{gap} for a DBR laser diode may be 0.5 μm. At this dimension, the grating coupling coefficient K may be about 650-690 cm⁻¹ and may be almost independent of the III-V ridge width. The number of mirror pairs required for almost 100% reflectance may be about 250. The period of the grating may be in the range of 236 nm to 238 nm and this translates to a cavity length of about 60 μm. In this particular heterogeneous III-V on thin-SOI DBR LD, the symmetric side grating may be embedded underneath the active III-V ridge. As far as the optical mode is concerned, the DBR may be active and may provide gain with carrier injection. By keeping K high in the rear DBR mirror, the penetration depth may be kept to the minimum and this may reduce the length of the P-metal electrode over the rear DBR. This may in turn reduce the surface area of the P-contact and hence, may reduce the threshold current. For gap-width of 0.5 μm with coupling coefficient of about 650-690 cm⁻¹, the Bragg decay length may be about ˜14.5 μm, as given by 1/|κ|. This implies that if the DBR laser diode employs the highest possible κ for both the front and back mirrors, the estimated L_{cav} may be about 20˜40 μm while allowing power output at both ends. Based on just the cavity length, the estimated F3dB bandwidth for a direct modulated DBR laser diode may be about 20 to 30 GHz.

In a conventional DBR laser diode, the DBR mirrors are usually passive and are not part of the active laser cavity. For a heterogeneous III-V on SOI platform, the conventional passive gratings may be patterned on the SOI waveguide. In this approach, the grating depth must be well controlled which may be difficult for a large number of devices on a large wafer. If the etched grating is too deep, mode-mismatch through the grating and optical scattering loss would become a critical problem. Furthermore, if this approach is employed in a thin SOI device, the depth control may be even more critical as the percentage error per unit etch depth variation is higher for a thinner SOI. The tightness in etch depth control is more severe for DFB or DBR laser diodes employing a central grating structure.

An optical device according to various embodiments, may be a thin-SOI hybrid III-V DBR laser diode including a plurality of DBR mirrors. The DBR mirrors may include symmetric side gratings in a SOI substrate embedded beneath a bonded III-V epitaxy. The central gap-width of the symmetric side-gratings may provide an added parameter of control on the grating coupling coefficient κ. For a symmetric side grating gap-width of 0.5 μm, the reflection may be more sensitive to grating etch-depth in comparison to cases where the gap widths are wider at 1.4 μm and 1.7 μm, as shown in FIG. 11. FIG. 28 shows that the DBR reflectance may be largely controllable by gap widths. The grating depth can be fixed for all devices and κ can be varied by simply varying the central gap width. The tightness on the manufacturing control of grating depth may be eased, by having the value of κ solely varied through the gap width. The gap width is the distance between a row of gratings arranged away from the longitudinal axis in a first direction and another row of gratings arranged away from the longitudinal axis in a second direction, wherein the second direction is different from the first direction. The reflectance now depends on the gap width which may be well controlled by lithography and, hence, may provide better control of the reflectance even for a large number of on-wafer devices. Grating based laser diode may require optical mode-matching and the field perturbation by the grating must not be too large as to cause mode-mismatch. Mode-mismatch may result in radiation or scattering loss. Hence, the fundamental benefit of using the symmetric side grating is that it may ensure mode-matching between grating and non-grating regions of the fundamental mode. In comparison, the central grating scheme may require a sufficiently large grating aspect ratio (transverse-width×grating-period) to ensure mode matching of the fundamental mode, which may be difficult to fabricate.

According to various embodiments, an optical device may include active DBR mirrors. In other words, optical gain is incorporated in the DBR mirrors during carrier injection. Symmetric side grating with narrow gap-widths may be utilized for a highly reflective DBR. The front DBR and the rear DBR may have differing gap widths to provide for low reflectivity at the front and high reflectivity at the rear DBR. A wider gap-width at the front DBR may also improve thermal impedance and may results in a higher maximum output power.

Another benefit of utilizing the symmetric side grating is that the aspect ratio in the dimension of the gratings in terms of (grating transverse width x grating period) may be smaller and, hence, easier to be printed using Ebeam lithography or even projection mode photolithography, in comparison to DFB or DBR devices based on central grating configuration. The resist integrity of large aspect ratio grating patterns may be compromised by the collapse of the grating resist after liquid development due to capillary force. In such a situation, a second order grating is usually used for large aspect ratio grating, although second order grating DFB or DBR may have lower energy efficiency. An optical device according to various embodiments may have a lower aspect ratio grating is used as first order gratings can be employed.

A DBR laser diode according to various embodiments, may include a short up-down coupling taper, and a thin SOI substrate of about 300 nm in thickness. The short up-down coupling taper may provide a faster up-down coupling time while the thin SOI substrate may provide a higher confinement factor in the active layer and, hence, lower the threshold current density.

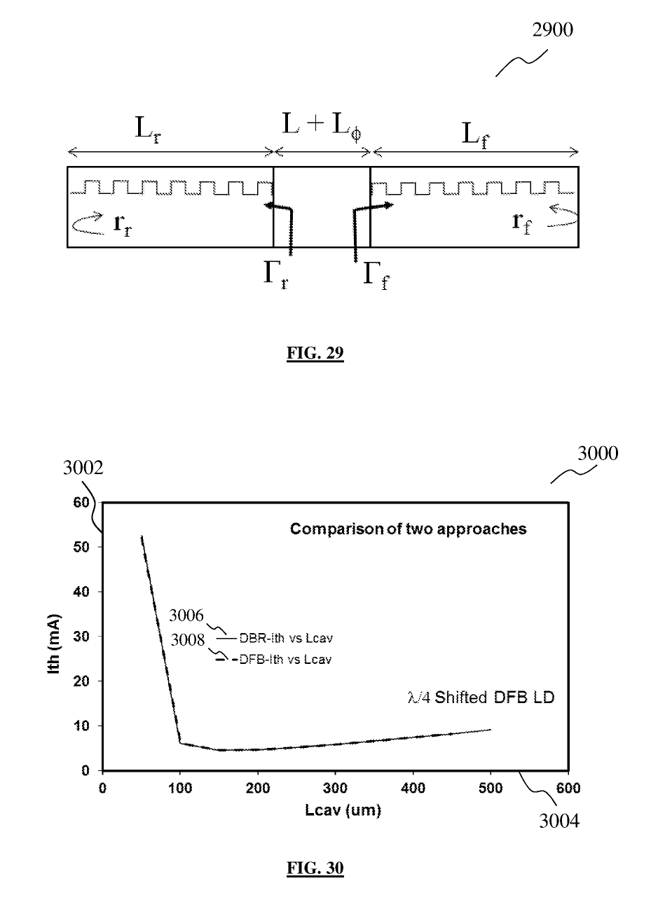

FIG. 29 shows an analytical model 2900 for derivation of characteristic equation for threshold condition. The threshold current may be used to obtain the optimized cavity length from the relationship between the threshold current and the cavity length. The previous characteristic Equations (3) and (4) are valid only for a DFB structure with a single phase-shifted region at the center of the cavity. For a DFB laser diode with an extended phase shift length or a DBR laser diode with active grating, a more general analytical model may be needed. The analytical model 2900 shows a more general analytical model for the cavity which consists of a central gain and a phase shift region which has no grating, coupled with rear and front DBR mirrors which include gratings. In the analytical model 2900, only refractive index coupled gratings are considered. The central region without grating has a total length of (L+L_{φ}), where L_{φ} is the length which accounts for the π/2 phase-shift and L is the extended length of the central region. L can be designed such that the phase shift over 2L are integer multiples of 2π so that the net phase-shift may be accounted solely by L_{φ}. Lᵣ and L_{f} are the lengths of the rear DBR and front DBR, respectively. rᵣ and r_{f} are the facet reflectance of the rear and front facets, respectively. Γᵣ and Γ_{f} are the effective DBR reflectance as seen from the central extension region to the rear and front, respectively. They can be derived from coupled mode equations and are given in Equation (6). The subscript i in Equation (5) through Equation (7) is either i=r or i=f In Equation (5), g may be the threshold gain. The characteristic equation for the threshold condition may be given by Equation (5):

$$\begin{matrix}{Γ}_{r} {Γ}_{f} exp ( gL ) exp ( j β {L}_{φ} ) = 1 & Equation ( 5 ) \\ {Γ}_{i} = \frac{{R}_{i} ( 1 - {R}_{i} {r}_{i} ) - ( {R}_{i} - {r}_{i} ) exp ( 2 {γ}_{i} {L}_{i} )}{( 1 - {R}_{i} {r}_{i} ) - {R}_{i} ( {R}_{i} - {r}_{i} ) exp ( 2 {γ}_{i} {L}_{i} )} & Equation ( 6 ) \\ {R}_{i} = \frac{- j {κ}_{i}}{{γ}_{i} + ( j δ + g )} & Equation ( 7 )\end{matrix}$$

In order to validate the model 2900, a λ/4-DFB LD structure with zero end facet reflectivities rᵣ and r_{f} and with π/2 phase-shift region at the center of the structure can be considered using both the model 2100 in FIG. 21 with Equation (3), and the model 2900 with Equation (5). The threshold current against cavity length relations have been derived for the same λ/4-DFB LD using the two models. The physical and material parameters in Table 2200 of FIG. 22 have been utilized for both models.

FIG. 30 shows a grah 3000 showing the threshold current plotted against cavity length of λ/4-shifted DFB LD with zero end facet reflectivities at both ends done by both approaches in the model 2100 of FIG. 21 for a DFB optical device and the model 2900 of FIG. 29 for a DBR optical device. The graph 3000 includes a vertical axis 3002 indicating threshold current in milliamperes and a horizontal axis 3004 indicating L_{cav} in um. Data in the graph 3000 shows exact match of the two results by both approaches. This validates the model 2900 against the model 2100. Using the model 2900, the threshold current against cavity length relations were derived for case of symmetric side grating DFB LD's using central gap-width of 1.4 μm for all cases each with phase-shift region and extension region at the center of the cavity. The phase region has length of L_{φ} which is given a value such that, βL_{φ}=π/2. Both the front and rear facet reflectivities are taken to be zero.

FIG. 31 shows a graph 3100 showing the threshold current plotted against cavity length for both λ/4-shifted DFB LD with central extensions of 60 μm and 120 μm for the quarter-wave region. The graph 3100 includes a vertical axis 3102 indicating current threshold in milliamperes and a horizontal axis 3104 indicating L_{cav} in um. The graph 3100 further includes a first plot 3106 representing the plot when the central extension is 60 um; and a second plot 3108 representing the plot when the central extension is 120 um. In the graph 3100, extension regions of lengths 60.2 um and 120.16 um were considered. Each extension region may be length adjusted such that exp((βL) is multiples of 2π. The III-V ridge widths for both DFB laser diodes are 2 μm. Optical gain may also be incorporated into the extension region.

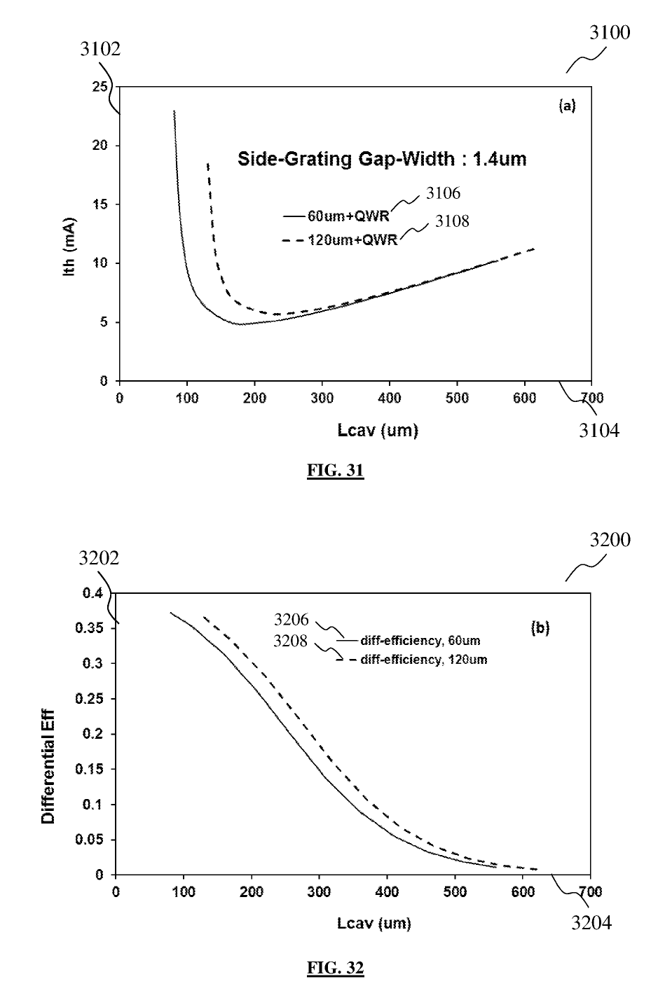

FIG. 32 shows a graph 3200 showing the differential quantum efficiency plotted against cavity length. The graph 3200 shows the double-ended differential quantum efficiency which is given by the Equation (8). The graph 3200 includes a vertical axis 3202 indicating differential efficiency and a horizontal axis L_{cav} in um. The graph 3200 includes a first plot 3206 representing the plot when the extension region length is 60 um; and a second plot 3208 representing the plot when the extension region length is 120 um.

$$η = \frac{g}{g + {α}_{int}} = ( 1 - \frac{{α}_{int}}{{g}_{th}} ) \qquad Equation ( 8 )$$

where g is the loss due to the distributed feedback grating mirror. gₜₕ is the overall threshold gain which is the sum of mirror loss and internal loss, αᵢₙₜ. From FIGS. 31 and 32, it can be seen that for the same cavity length for both cases with extensions of 60.4 μm and 120.16 μm, the latter case has shorter DBR grating lengths for both rear and front DBRs. The facet reflectivities are zero. The effective mirror reflectivity due to the gratings is less for the 120.16 μm extension case. Hence, longer central extension length device gives slightly higher differential quantum efficiency as shown in FIG. 32. As cavity lengths increases, the output power from both facets decreases because more and more optical power is confined in the cavity. The optimized cavity length is 150˜200 μm where threshold current is minimum and differential quantum efficiency is high at about 30-35%. For 120.16 μm extension case, the threshold current is larger because the effective DBR loss is larger for same cavity length. For cavity length larger than 300 μm, the DBR mirror losses are small for both device, and the αᵢₙₜ, becomes increasingly significant for both cases to almost no difference in the threshold current between the two cases. The threshold current for both cases converges beyond cavity length of 300 μm.

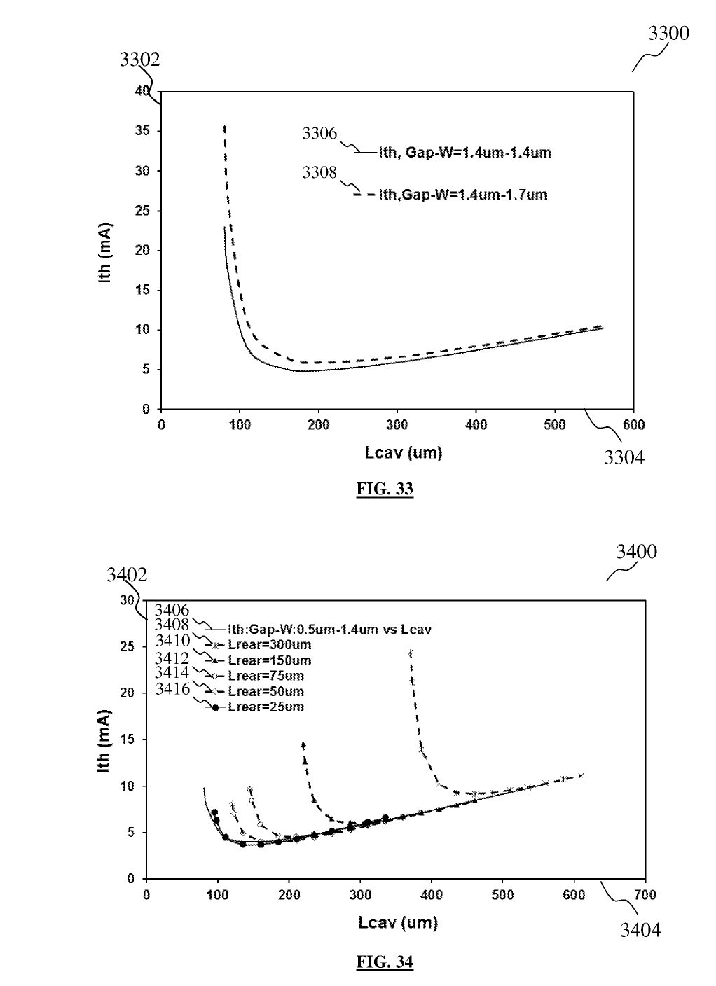

FIG. 33 shows a graph 3300 showing threshold current plotted against cavity length for λ/4-phase shift and 60.4 μm central extension, and III-V ridge width of 2 μm. The graph 3300 includes a vertical axis 3302 indicating threshold current in milliamperes and a horizontal axis 3304 indicating L_{cav} in um. The graph 3300 further includes a first plot 3306 for side-grating DBR LD with central widths of 1.4 μm for both rear and front; and a second plot 3308 for side-grating DBR LD with central widths of 1.4 μm and 1.7 μm for rear and front DBR. The graph 3300 is a plot of threshold current against cavity length for central extension of length 60.2 μm plus a λ/4-phase shift region, III-V ridge width of 2 μm, and for zero facet reflectivities. For the solid data curve, both the rear and front DBR have gap-widths of 1.4 μm. For the dashed data curve, the rear DBR has gap-width of 1.7 μm and front DBR has gap-width of 1.4 μm. For gap-widths of 1.4 μm and 1.7 μm, the coupling coefficients are 115 cm-1 and 57 cm-1, respectively. These correspond to Bragg decay lengths of 86.4 μm and 174.6 μm, respectively. For case with DBR gap-width of 1.7 μm, lower coupling coefficient gives rise to higher DBR mirror loss and hence, gives higher threshold current for all cavity lengths.

FIG. 34 shows a graph 3400 showing the threshold current plotted against total cavity length for rear DBR gap-width of 0.5 μm, front DBR gap-width of 1.4 μm, III-V ridge-width of 2 μm. Black smooth curve is for the case of Lᵣₑₐᵣ=L_{front}, and the other dashed data curves are for various fixed Lᵣₑₐᵣ of 300 μm, 150 μm, 75 μm, 50 μm, and 25 μm, while L_{front} is varied. The graph 3400 includes a vertical axis 3402 indicating current threshold in milliamperes and a horizontal axis 3404 indicating L_{cav} in um. The graph 3400 further includes a first plot 3406 for the plot when the rear cavity length is equal to the front cavity length; a second plot 3408 for the plot when the rear cavity length is 300 μm; a third plot 3410 for the plot when the rear cavity length is 150 μm; a fourth plot 3412 for the plot when the rear cavity length is 75 μm; a fifth plot 3414 for the plot when the rear cavity length is 50 μm; and a sixth plot 3416 for the plot when the rear cavity length is 25 μm. The graph 3400 shows the plot of threshold current against cavity lengths for various cases of DBR LD with λ/4 phase shift region, 60.2 μm extension at the central region of the DBR LD, zero facet reflectivities, and III-V ridge-width of 2 μm. In these cases, the rear DBR utilizes symmetric side-grating gap-width of 0.5 μm and the front DBR utilizes symmetric side gating gap-width of 1.4 μm. For gap-width of 0.5 μm, the coupling coefficient is 480 cm-1 and the Bragg decay length is 21 μm. In this scheme of using symmetric side grating in DBR LD, small gap-width gives short Bragg decay length and hence, lowest possible threshold current because the effective area of current injection by P-metal contact required is less. The smooth black data curve is the Iₜₕ against L_{cav} curve for a symmetrical structure wherein Lᵣₑₐᵣ=L_{front}. L_{cav} is the total sum of Lᵣₑₐᵣ, L_{front}, extension-region length, and λ/4-phase-shift region length. The lowest possible threshold current is about 5 mA and cavity length (L_{cav}) of 150˜200 μm. For the other data curves in the graph 3400, Iₜₕ against L_{cav} were plotted for various cases of rear DBR lengths. i.e. Lᵣₑₐᵣ of 300 μm, 150 μm, 75 μm and 50 μm. These data shows that if Lᵣₑₐᵣ is larger than the Bragg decay length of the rear mirror (21 μm), it gives rise to unnecessary large threshold current. As the Lᵣₑₐᵣ is reduced, the minimum optimized threshold currents are on the reducing trend. The dashed data curves finally converge toward the solid smooth curve in the graph 3400 as Lᵣₑₐᵣ is reduced below 50 μm toward 25 μm. Threshold current is the current injection required to achieve gain compensating the loss. From the results of the graph 3400, when the gap-width of the rear DBR is 0.5 μm, the Bragg decay length or the optical penetration depth in the rear DBR is about 21 μm at ridge-width of 24 μm. By having a large rear κ₁, and sufficient length of rear DBR of 25 μm, the rear optical reflectivity is near to 100% and practically no power is emitted at the rear.

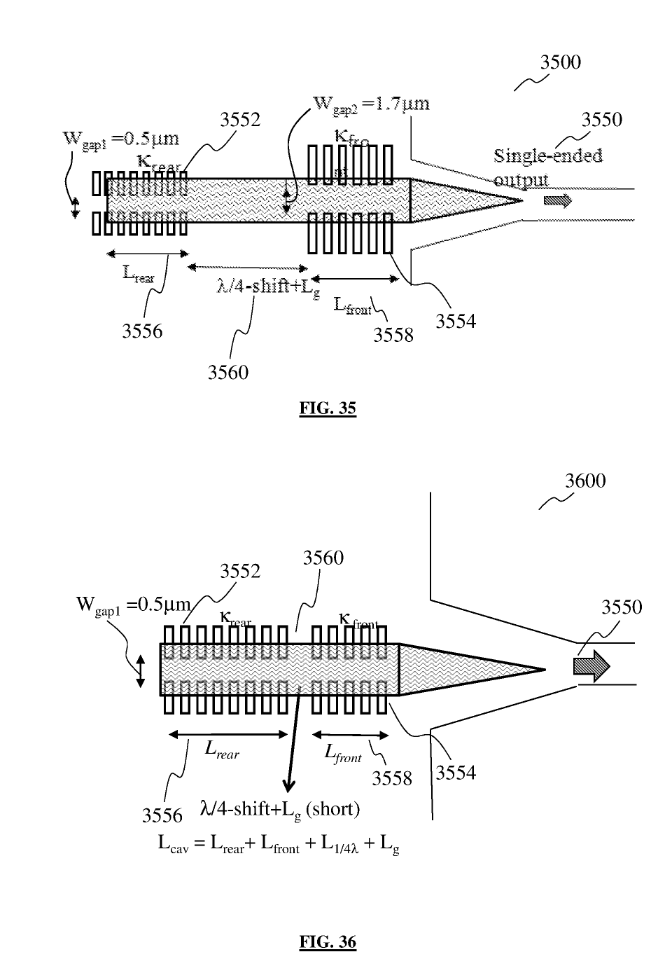

FIG. 35 shows a top-down schematic diagram of an optical device 3500 according to various embodiments. The optical device 3500 may be a heterogeneous III-V on thin-SOI DBR laser diode. The optical device 3500 may have a single-ended output 3550. The optical device 3500 may include a rear set of gratings 3552 and a front set of gratings 3554. The gap width W_{gap1} of the rear set of gratings 3552 may be about 0.5 μm while the gap width W_{gap2} of the front set of gratings 3554 may be about of 1.7 μm. The cavity length of the rear set of gratings 3552 may be denoted as Lᵣₑₐᵣ 3556 while the cavity length of front set of gratings 3554 may be denoted as L_{front} 3558. The rear set of gratings 3552 may have a high grating coupling coefficient, κ₁=480 cm⁻¹ to ensure that the Lᵣₑₐᵣ may be short and may cover the Bragg decay length so that the threshold current may be minimized. The front set of gratings 3554 may have a low coupling coefficient, κ₂ with sufficient L_{front} for reflectivity of about 50% for the optical output at the single-ended output 3550. κ₂ may be low so as to provide sufficient feedback and to ensure a high differential efficiency. A central region 3560 separates the front set of gratings 3554 from the rear set of gratings 3552. The central region 3560 may include a λ/4-phase shift region for single mode emission and a length L_{g} which corresponds to a phase of integer multiples of 2π. As light is permitted to emit only from the single-ended output 3550, no up-down coupler is required at the rear. Therefore, the up-down coupler loss is reduced to one at the front, instead of two. This further reduces loss and the threshold current. The utilization of symmetric side gratings in the rear set of gratings 3552 and the rear set of gratings 3554 allows the grating coupling coefficient of the each set of gratings to be designed by both the respective grating gaps and the respective grating depths, while a central grating scheme as seen in FIG. lA limits the grating coupling coefficient to be controlled only by the grating depth. Control of variations in the grating depth can be very difficult in a thin SOI structure. In contrast, the grating gap width can be easily controlled in the lithography process.

FIG. 36 shows a schematic diagram of an optical device 3600 according to various embodiments. The optical device 3600 may be an alternative embodiment of a heterogeneous III-V on thin-SOI DBR laser diode. The optical device 3600 may have a single-ended output 3550. The optical device 3600 may be suited for direct-modulation high speed operation. The optical device 3600 may be used in an intra-chip or inter-chip optical interconnect applications. The optical interconnect applications may employ direct modulation of the laser diode. The laser diodes may emit an optical power in the order of 1˜5 mW. The laser diode may have a short cavity length so as to achieve a large relaxation oscillation frequency and a high photon density in the cavity. The W_{gap} may be the same for both the rear set of gratings 3552 and the front set of gratings 3554. The W_{gap} may be about 0.5 μm. The rear set of gratings 3552 may include a larger number of grating element pairs as compared to the front set of gratings 3554. The number of grating element pairs in the rear set of gratings 3552 may be large enough for almost 100% reflectivity. The number of grating element pairs in the front set of gratings 3554 may be small to provide a sufficiently low reflectivity so as to allow an optical output at the single-ended output 3550. The central region 3560 may include just a λ/4-phase shift region or a λ/4-phase shift region plus a short L_{g} for desired output optical power.

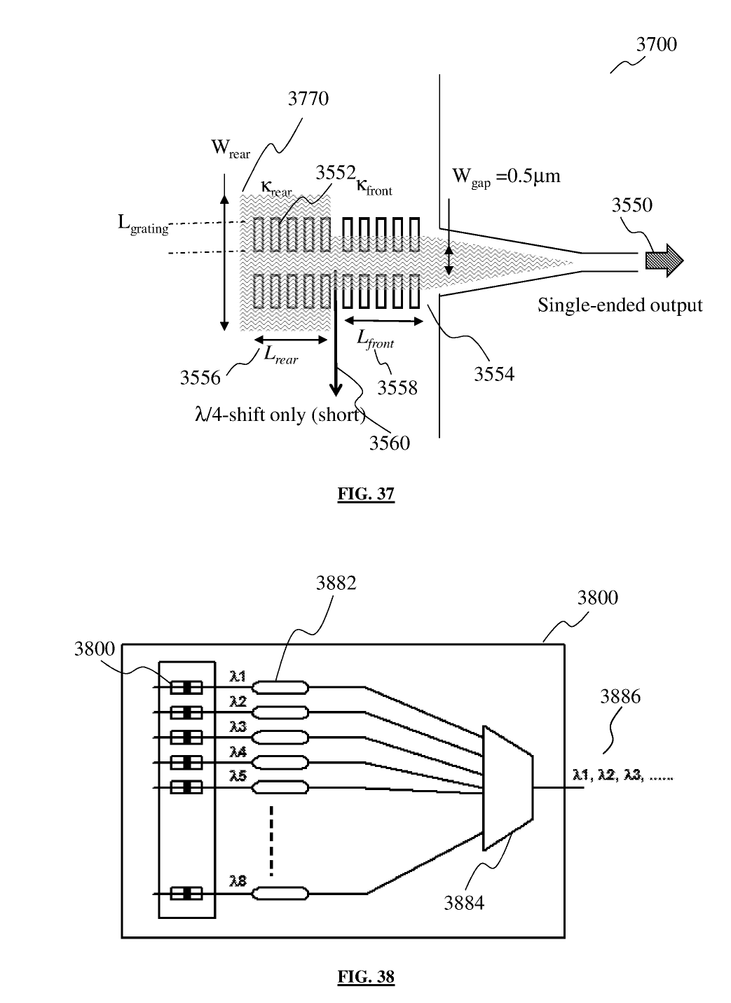

FIG. 37 shows a schematic diagram of an optical device 3700 according to various embodiments. The optical device 3700 may be a heterogeneous DBR laser diode configured to emit single wavelength light. The optical device 3700 may be directly modulated at a high speed. In contrast to the optical device 3600 of FIG. 36, higher κᵣₑₐᵣ may be obtained by having a W_{gap} of about 0.4 μm to 0.5 μm with the set of rear gratings 3552 arranged underneath a wider III-V ridge 3770. The III-V ridge 3770 may have a wider ridge width at the beginning of the rear set of gratings 3552. The central region 3560 may include just a λ/4-phase shift region, while the front set of gratings 3554 may include a plurality of grating element pairs for a 50˜60% reflectance. The optical device 3700 may be useful for optical interconnects which require high speed direct-modulation. For example, the III-V ridge 3770 may have a width of about 6˜7 μm at a rear end and a ridge width of about 2 μm at the front end while the grating gap width is about 0.4˜0.5 μm throughout the optical device 3700. The expected F3dB may be about 30 GHz.

FIG. 38 shows a schematic diagram showing a transmitter chip 3800 according to various embodiments. The transmitter chip 3800 may be an integrated heterogeneous III-V on SOI transmitter chip. The transmitter chip 3800 may include a plurality of laser diodes 3880 of various wavelengths and a corresponding plurality of modulators 3882. Each laser diode 3880 may be coupled to a respective on-chip modulator 3882. Each laser diode 3880 may be self-aligned to a modulator 3882. In other words, the transmitter chip 3800 may have a plurality of laser diodes 3880 arranged in an external modulation scheme. An external modulation scheme may have inherent disadvantages. The modulators 3882 may be micro-ring modulators which require on-chip heaters, thereby resulting in lower energy efficiency for the transmitter chip 3800. The modulators 3882 may also be Mach-Zehnder modulators which may cause the transmitter chip 3800 to have a long footprint. The laser diodes 3880 may be tunable DFB laser diodes while the modulators 3882 may be SOI-based modulators. The outputs of the plurality of modulators 3882 may be multiplexed to a single multi-wavelength output 3886 through a combiner or a multiplexer 3884. The output 3886 may be a WDM light source coupled to a fiber through a fiber-to-chip coupler. The laser diodes 3880 may be the optical device 200A of FIG. 2A or the optical device 200B of FIG. 2B. The laser diodes 3880 may be configured to provide the WDM light. The modulators 3882 may be configured to perform electrical-to-optical conversion.

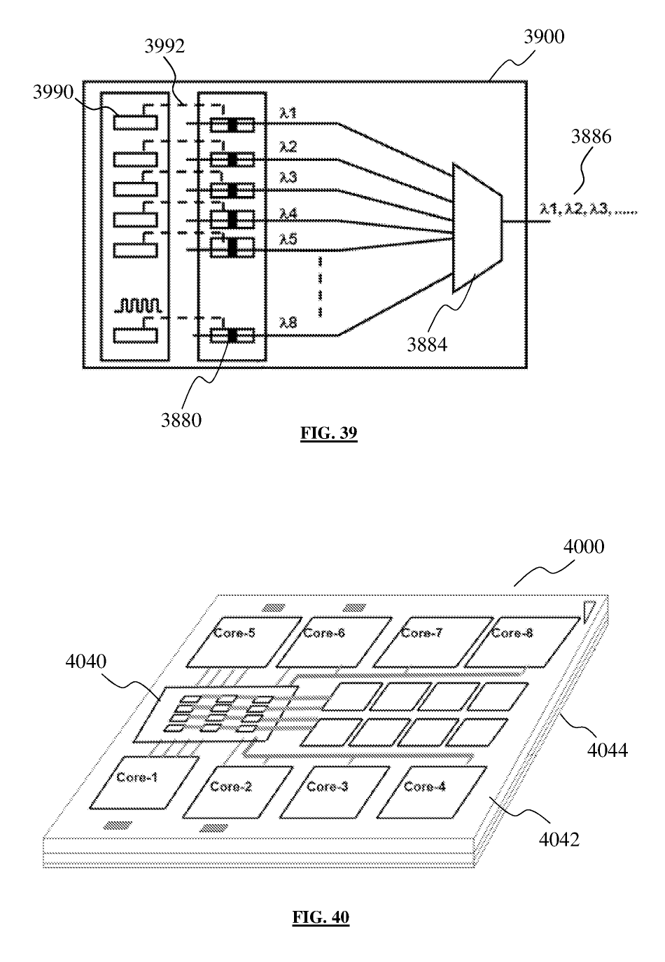

FIG. 39 shows a schematic diagram of a transmitter chip 3900 according to various embodiments. The transmitter chip 3900 may employ a direct modulation scheme, unlike the transmitter chip 3800 of FIG. 38. The transmitter chip 3900 may be an integrated heterogeneous III-V on SOI transmitter chip. The transmitter chip 3900 may include a plurality of laser diodes 3880. Each laser diode 3880 may be configured to provide light at a different wavelength from the other laser diodes 3880 such that the plurality of laser diodes 3880 may collectively provide a broadband light. The laser diodes 3880 may be tunable DFB laser diodes. Instead of coupling each laser diode 3880 to an external modulator, the transmitter chip 3900 may couple an electronic driving signal circuit 3990 to each laser diode 3880. The electronic driving signal circuit 3990 may be configured to provide a high frequency electronic driving signal 3992 to directly modulate the output of the laser diodes 3880. The transmitter chip 3900 may have the advantage of not requiring on-chip heaters. The plurality of laser diodes 3880 may be multiplexed to a single multi-wavelength output 3886 through a combiner or a multiplexer 3884. The output 3886 may be a WDM light source coupled to a fiber through a fiber-to-chip coupler. The laser diodes 3880 may be the optical device 200A of FIG. 2A or the optical device 200B of FIG. 2B. The direct modulation scheme may achieve a high bandwidth of at least substantially equal to or more than 40 Gbits per second.

FIG. 40 shows a schematic diagram of a multi-core chip 4000 according to various embodiments. The multi-core chip 4000 may include a plurality of cores coupled to an on-chip laser array 4040. The laser array 4040 may include a plurality of laser diodes. The multi-core chip 4000 may include an optical guiding layer 4042 over an electronics layer 4044. The laser array 4040 may be configured to provide a multi-wavelength light. The laser array 4040 may be configured to function as part of an intra-chip optical interconnects. The laser diodes 3880 may be the optical device 200A of FIG. 2A or the optical device 200B of FIG. 2B. The laser diodes may need to be integratable on silicon or a SOI platform, small in footprint and low in power consumption in order to be used as the laser source for the multi-core chip 4000. The laser diodes may also need to have a high modulation bandwidth and be operable at elevated temperatures up to 120° C. The laser diodes may be configured to provide light with scalable wavelengths so that the laser array 4040 may be configured to provide WDM light source. Each laser diode may be integrated to a functional block configured to directly modulate the light output of the each laser diode.

While embodiments of the invention have been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced. It will be appreciated that common numerals, used in the relevant drawings, refer to components that serve a similar or the same purpose.

1. An optical device comprising:
a first waveguide configured to guide a light wave along a longitudinal axis;
a first grating at least partially formed in the first waveguide, the first grating arranged away from the longitudinal axis in a first direction; and
a second grating at least partially formed in the first waveguide, the second grating arranged away from the longitudinal axis in a second direction;
wherein the second direction is different from the first direction.

2. The optical device of claim 1, wherein the second direction opposes the first direction.

3. The optical device of claim 1, wherein the first grating is arranged at a first distance away from the longitudinal axis; and wherein the second grating is arranged at the first distance away from the longitudinal axis.

4. The optical device of claim 1, wherein the first grating comprises a first plurality of grating elements arranged in a first row and wherein the second grating comprises a second plurality of grating elements arranged in a second row.

5. The optical device of claim 4, wherein each of the first row and the second row is arranged at least substantially parallel to the longitudinal axis.

6. The optical device of claim 4, wherein each grating element of the second plurality of grating elements mirrors a respective grating element of the first plurality of grating elements about the longitudinal axis.

7. The optical device of claim 1, further comprising:
a second waveguide arranged over the first waveguide to at least partially overlap each of the first grating and the second grating.

8. The optical device of claim 7, wherein a central axis of the second waveguide is in between the first grating and the second grating.

9. The optical device of claim 7, wherein the second waveguide comprises at least one coupling end configured to couple the light wave between the first waveguide and the second waveguide.

10. The optical device of claim 9, wherein the at least one coupling end is tapered.

11. The optical device of claim 9, wherein the at least one coupling end comprises charge carriers.

12. The optical device of claim 1, further comprising:
a third grating at least partially formed in the first waveguide, the third grating arranged away from the longitudinal axis in the first direction; and
a fourth grating at least partially formed in the first waveguide, the fourth grating arranged away from the longitudinal axis in the second direction.

13. The optical device of claim 12, wherein the third grating is arranged at a second distance away from the longitudinal axis; and wherein the fourth grating is arranged at the second distance away from the longitudinal axis.

14. The optical device of claim 12, wherein each of the first grating and the second grating is arranged at a front end of the first waveguide; wherein each of the third grating and the fourth grating is arranged at a rear end of the first waveguide; wherein the rear end opposes the front end.

15. The optical device of claim 13, further comprising:
a second waveguide arranged over the first waveguide to at least partially overlap each of the first grating, the second grating, the third grating and the fourth grating.

16. The optical device of claim 15, wherein a portion of the second waveguide at least partially overlapping each of the third grating and the fourth grating is larger than a further portion of the second waveguide at least partially overlapping each of the first grating and the second grating.

17. The optical device of claim 12, wherein the first distance is larger than the second distance.

18. The optical device of claim 12, wherein each of the third grating and the fourth grating comprise more grating elements than each of the first grating and the second grating.

19. The optical device of claim 1, wherein a grating coupling coefficient of the optical device is dependent on the first distance.

20. A method for fabricating an optical device, the method comprising:
providing a first waveguide configured to guide a light wave along a longitudinal axis;
forming a first grating at least partially in the first waveguide, wherein the first grating is arranged away from the longitudinal axis in a first direction; and
forming a second grating at least partially in the first waveguide, wherein the second grating is arranged away from the longitudinal axis in a second direction;
wherein the second direction is different from the first direction.
